(19) United States
(12) Patent Application Publication
(10) Pub. No.: US 2010/0329069 A1
(43) Pub. Date: Dec. 30, 2010

(54) SEMICONDUCTOR MEMORY DEVICE

(75) Inventors: Gaku Ito, Kawasaki (JP); Yousuke Kawashima, Kawasaki (JP); Yasuhide Sosogi, Kawasaki (JP); Satofumi Honda, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 12/818,600

(22) Filed: Jun. 18, 2010

(30) Foreign Application Priority Data
Jun. 26, 2009 (JP) 2009-152415

(51) Int. Cl. G11C 8/10; G11C 8/00

(52) U.S. Cl. 365/230.06; 365/230.08; 365/189.07

(57) ABSTRACT

A semiconductor memory device includes a plurality of memory cells that respectively stores data, a comparator that compares a row address in a previous cycle with a row address in a current cycle, and outputs a control signal to the row address decoder when the comparator detects a matching of a row address in a previous cycle and a row address in a current cycle, and a row address decoder that decodes the row address, and outputs a word line select signal to select one of word lines connected to a part of the plurality of memory cells based on the decoded row address, and prevents the output of the word line select signal when the control signal outputted from the comparator is inputted to the row address decoder.

### CROSS-REFERENCE TO RELATED APPLICATION

This application is based upon and claims the benefit of priority of the prior Japanese Patent Application No. 2009-152415 filed on Jun. 26, 2009, the entire contents of which are incorporated herein by reference.

### FIELD

The embodiments discussed herein are related to a semiconductor memory device.

### BACKGROUND

Static random access memories (SRAMs) and dynamic random access memories (DRAMs) are available as random access memories (RAMs).

A memory cell array included in a RAM has a configuration in which a large number of memory cells for holding bit information are arranged at intersections of word lines and bit lines. The word lines are control signal lines for selecting a row in the memory cell array and column address select (CAS) signals are control signal lines for selecting a column in the memory cell array. The memory cells achieve a reading or writing operation of 1-bit data through changes in voltages of the word line and the column address select signal which correspond to a decoded address to which memory access is to be performed.

In order to read data from the memory cell, voltages are applied to the word line and the column address select signal which correspond to a decoded read address. Multiple memory cells are connected to one word line. During reading of data from the memory cell to be read, voltages are applied to other memory cells connected to the same word line of the memory cell to be read. Thus, the voltages applied to the other memory cells may be wasted.

The semiconductor memory device is described in Japanese Laid-open Patent Publication No. 4-42490, and Japanese Laid-open Patent Publication No. 2000-195253, for example.

### SUMMARY

According to an aspect of an embodiment, a semiconductor memory device includes a plurality of memory cells that respectively stores data, a comparator that compares a row address in a previous cycle with a row address in a current cycle, and outputs a control signal to the row address decoder when the comparator detects a matching of a row address in a previous cycle and a row address in a current cycle, a row address decoder that decodes the row address, and outputs a word line select signal to select one of word lines connected to a part of the plurality of memory cells based on the decoded row address, and prevents the output of the word line select signal when the control signal outputted from the comparator is inputted to the row address decoder, and a read latch that stores data read out from the part of the plurality of the memory cells selected based on the word line select signal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of on example of the configuration of a semiconductor memory device;

FIG. 2 illustrates a specific example of a comparator;

FIG. 3 illustrates a specific example of a row address decoder;

FIG. 4 illustrates a specific example of a column address decoder;

FIG. 5A is a diagram illustrating one example of a memory cell;

FIG. 5B is a diagram illustrating one example of the memory cell;

FIG. 6 illustrates a specific example of a bit-line precharge circuit;

FIG. 7 illustrates a specific example of a sense amplifier;

FIG. 8 illustrates a specific example of a memory circuit;

FIG. 9 illustrates a specific example of a multiplexer;

FIG. 10 is a block diagram illustrating one example of the configuration of the semiconductor memory device;

FIG. 11 illustrates a specific example of a write amplifier;

FIG. 12 illustrates one example of a timing chart of signals received by or supplied to the semiconductor memory device;

FIG. 13 is a block diagram illustrating one example of the configuration of the semiconductor memory device;

FIG. 14 illustrates a specific example of a comparator;

FIG. 15 illustrates a specific example of a sense amplifier;

FIG. 16 illustrates one example of a timing chart of signals received by or supplied to the semiconductor memory device;

FIG. 17 is a block diagram illustrating one example of the configuration of the semiconductor memory device;

FIG. 18 illustrates a specific example of an incrementer;

FIG. 19 illustrates one example of a timing chart of signals received by or supplied to the semiconductor memory device;

FIG. 20 is a block diagram illustrating one example of the configuration of the semiconductor memory device;

FIG. 21 illustrates a specific example of a comparator;

FIG. 22 illustrates a specific example of a memory circuit;

FIG. 23 illustrates one example of a timing chart of signals received by or supplied to the semiconductor memory device;

FIG. 24 is a block diagram illustrating one example of the configuration of the semiconductor memory device;

FIG. 25 illustrates a specific example of a comparator;

FIG. 26 illustrates a specific example of a write amplifier;

FIG. 27 illustrates one example of a timing chart of signals received by or supplied to the semiconductor memory device;

FIG. 28 is a block diagram illustrating one example of the configuration of the semiconductor memory device;

FIG. 29 is a logic table of a mode switching signal;

FIG. 30 illustrates a specific example of a comparator; and

FIG. 31 illustrates a specific example of a sense amplifier.

### DESCRIPTION OF EMBODIMENTS

Embodiments of a semiconductor memory device will be described below with reference to the accompanying drawings.

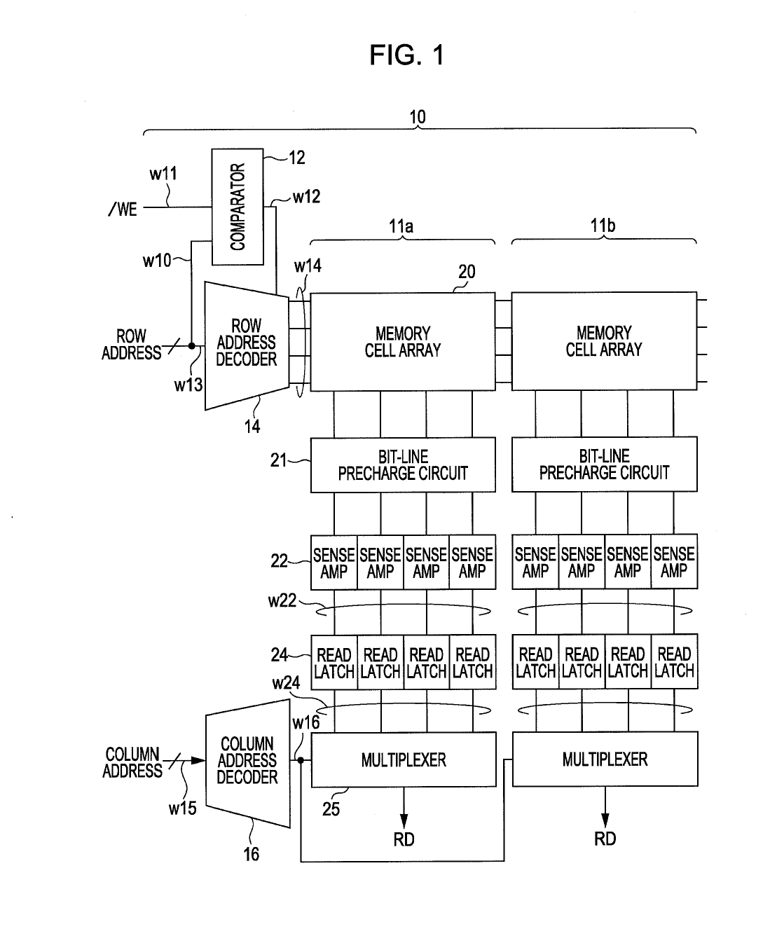

FIG. 1 is a block diagram of an example of the configuration of a semiconductor memory device. A semiconductor memory device 10 illustrated in FIG. 1 includes a comparator 12, a row address decoder 14, a column address decoder 16, memory cell array 20, bit-line precharge circuits 21, sense amplifiers (amp) 22, read latches 24, and multiplexers 25. The memory cell array 20, the bit-line precharge circuit 21, the sense amplifier 22, the read latch 24, and the multiplexer 25 may be coupled with each other through bit lines to constitute a memory block 11a. Memory cells included in the memory block 11a may be coupled with memory cells, included in another memory block 11b, through common word lines. Although examples of the semiconductor memory device are described below in connection with one memory block in order to prevent redundant description, a description for one memory block is also applicable to another memory block.

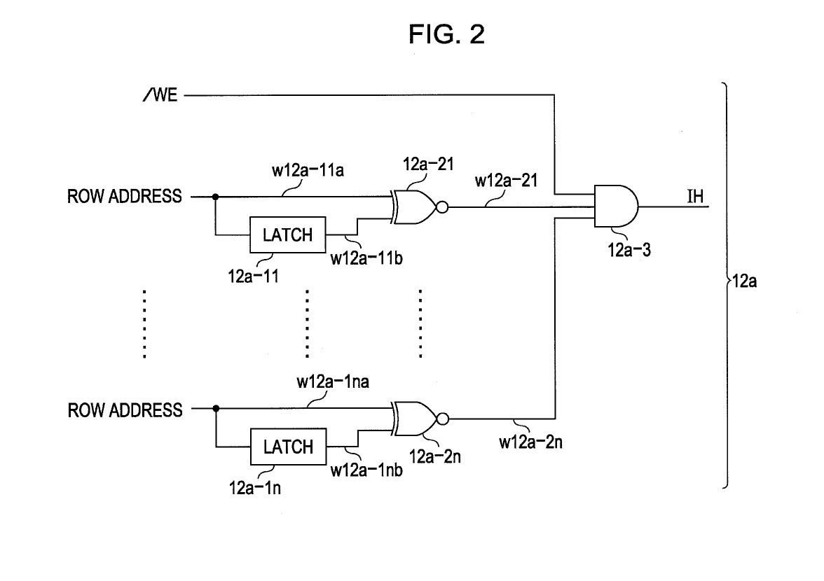

The comparator 12 is a circuit for comparing a row address in a previous cycle with a row address in the current cycle. The comparator 12 receives an externally supplied write enable (/WE: “/” means that a negative logic “0” indicates value of “true”) signal through a signal line w11 and also receives row address signals through n signal lines w10. The /WE signal is externally input to the comparator 12 so that a false value “1” thereof in negative logic indicates a read mode and a true value “0” in negative logic indicates a write mode. The write mode refers to a mode in which data is written to the memory cells and the read mode refers to a mode in which data is read from the memory cells. When the comparator 12 receives the row address signals and the /WE signal and a predetermined logic described below with reference to FIG. 2 holds true, the comparator 12 activates a control signal IH (InHibit) and outputs it to an input of the row address decoder 14 through a signal line w12. A specific example of the comparator 12 is described below with reference to FIG. 2.

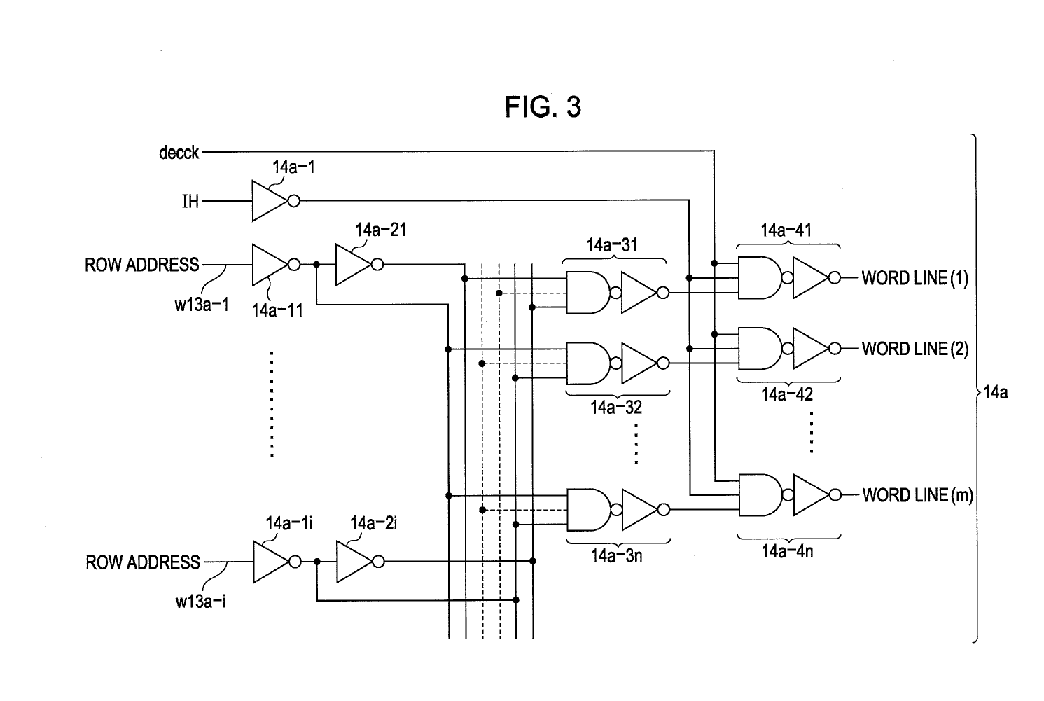

The row address decoder 14 serves as a circuit for decoding the received row address signals and activating a word line indicated by the values of the decoded row address signals. That is, the row address decoder 14 uses i-bit row address signals, received through i signal lines w13, to activate one of 2ⁱ word lines w14. The word lines w14 are signal lines connected to the word lines of the memory cell array 20. When the input control signal IH is activated, the row address decoder 14 stops the decoding operation. A specific example of the row address decoder 14 is described below with reference to FIG. 3.

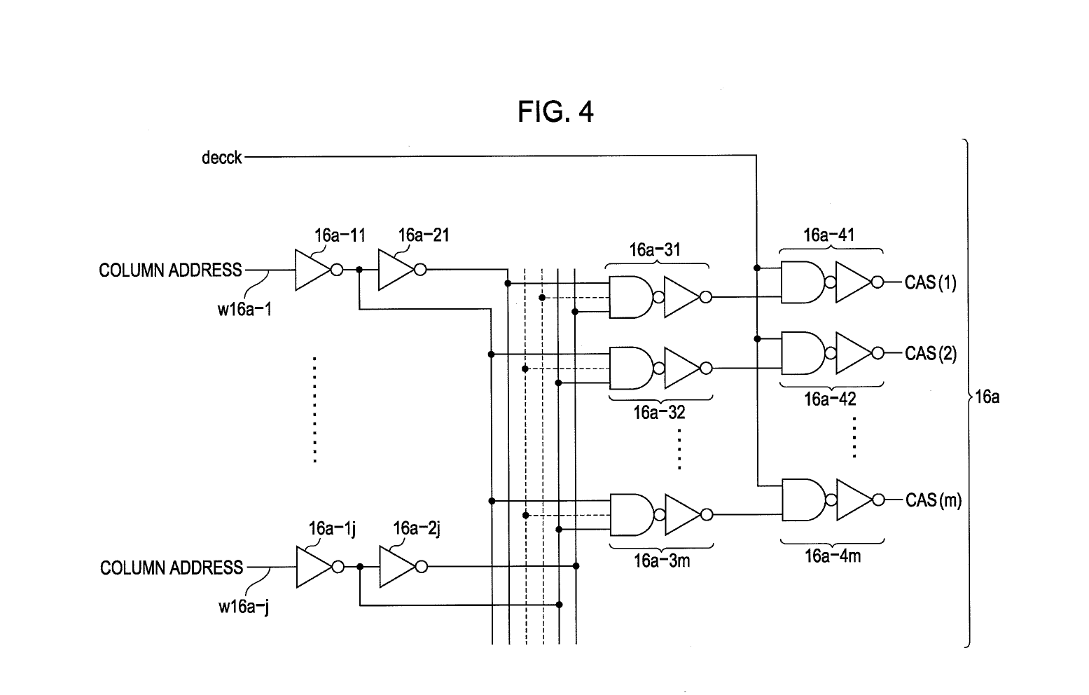

The column address decoder 16 serves as a circuit for decoding input column address signals and activating a column address select (CAS) signal indicated by the values of the decoded column address signals. The CAS signal is a signal for selecting the bit line of the memory cell array 20. The column address decoder 16 uses j-bit column address signals, received through j signal lines w15, to activate the CAS signal for one of 2^{j} CAS signal lines w16. A specific example of the column address decoder 16 is described below with reference to FIG. 4.

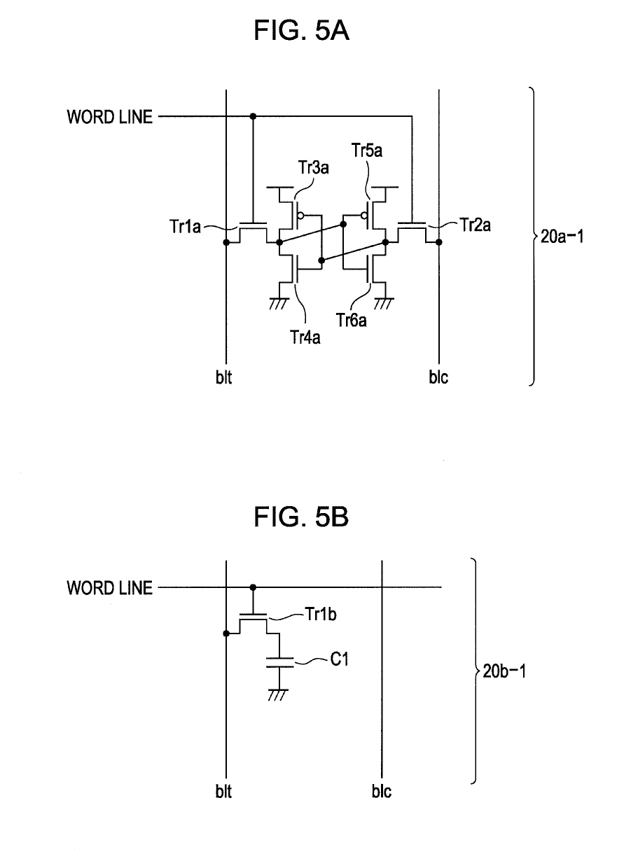

The memory cells in the memory cell array 20 are arranged in a matrix in row and column directions. Each memory cell stores data. The memory cell array 20 has word lines arranged in the row direction and has bit lines arranged in the column direction. Each memory address is specified by a unique address expressed by a row address in the row direction and a column address in the column direction. The memory cells are coupled with the word lines and the bit lines. Upon activation of the word lines and the bit lines, the memory cells receive or supply data. When the memory cell array 20 is, for example, an SRAM, each memory cell has a circuit configuration exemplified in FIG. 5A and described below. When the memory cell array 20 is, for example, a DRAM, each memory cell has a circuit configuration exemplified in FIG. 5B and described below.

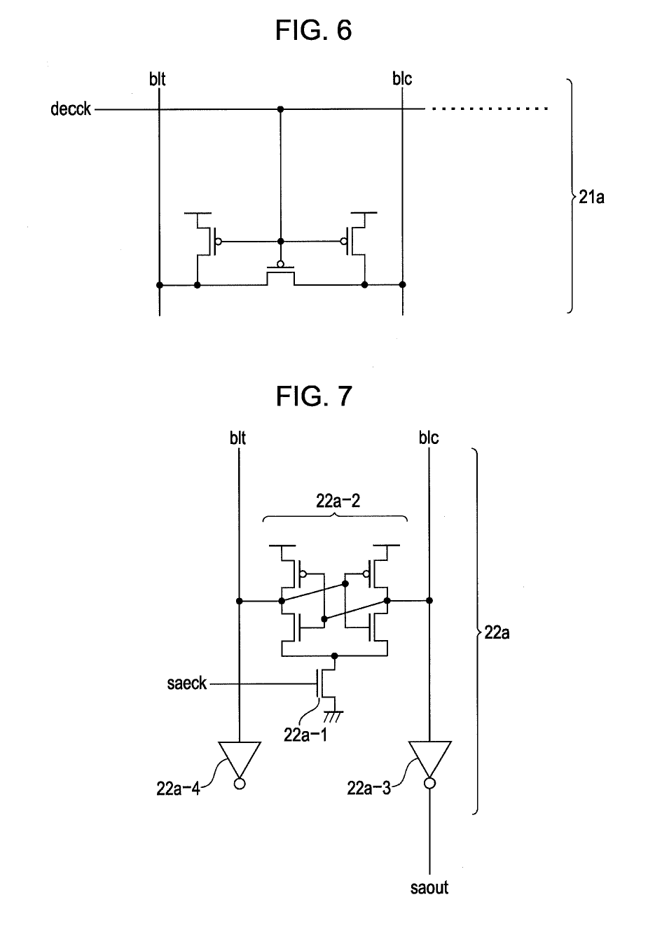

The bit-line precharge circuit 21 precharges both bit lines blt and blc to “1”. During the operation of the sense amplifier 22, the bit-line precharge circuit 21 stops the precharge operation. Inputs of the bit-line precharge circuit 21 are connected to the memory cell array 20 through the bit lines blt and blc. Outputs of the bit-line precharge circuit 21 are connected to inputs of the sense amplifier 22 through the bit lines bit and blc. A specific example of the bit-line precharge circuit 21 is described below with reference to FIG. 6.

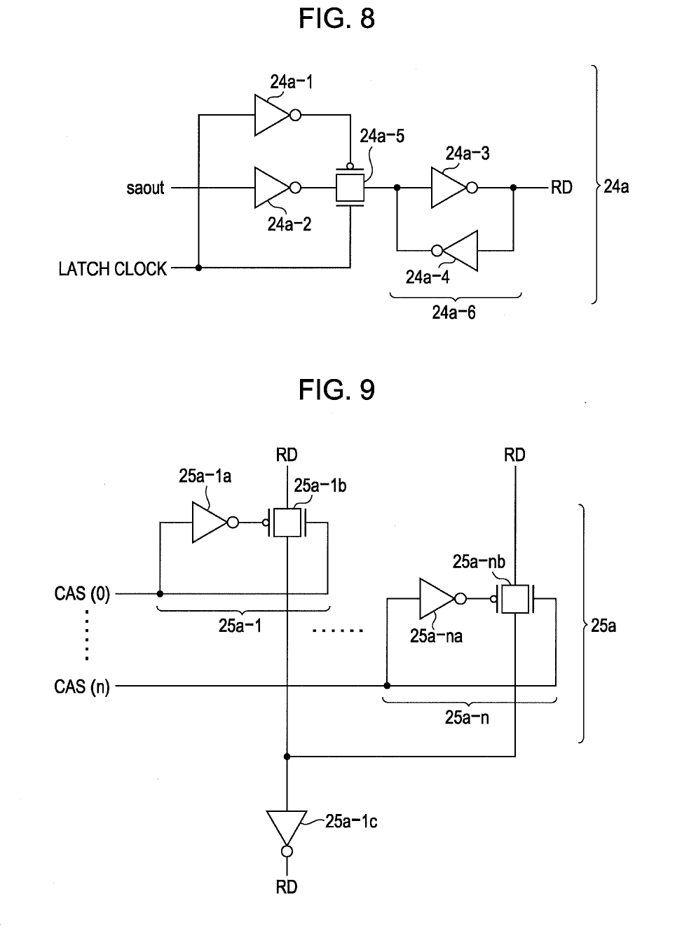

The sense amplifier 22 serves as a circuit for amplifying voltages output from the bit lines blt or blc of the memory cells. The inputs of the sense amplifier 22 are connected to the memory cell array 20 through the bit lines blt and blc and outputs of the sense amplifier 22 are connected to the read latch 24 through signal lines w22. A specific example of the sense amplifier 22 is described below with reference to FIG. 7. The read latch 24 serves as a circuit for temporarily holding read data amplified by the sense amplifier 22. Outputs of the read latch 24 are connected to the multiplexer 25 through signal lines w24. A specific example of the read latch 24 is described below with reference to FIG. 8.

FIG. 2 illustrates a specific example of a comparator. A comparator 12a illustrated in FIG. 2 corresponds to the comparator 12 illustrated in FIG. 1. The comparator 12a has latch circuits 12a-11 to 12a-1n, ENOR (Exclusive Not OR) circuits 12a-21 to 12a-2n for performing exclusive NOR (Not OR) operation, and an AND circuit 12a-3 for performing logical AND operation. The latch circuits 12a-11 to 12a-1n are provided for the corresponding row addresses. The ENOR circuits 12a-21 to 12a-2n are also prepared for the corresponding row addresses. When the value of a signal w12a-11b output from the latch 12a-11 that holds a row address in the previous cycle and the value of an input signal w12a-11a of the row address in the current cycle match each other, the ENOR circuit 12a-21 outputs a signal w12a-21 indicating “1”. Similarly, when the value of a signal w12a-1nb output from the latch 12a-1n that holds a row address in the previous cycle and the value of an input signal w12a-1na of the row address in the current cycle match each other, the ENOR circuit 12a-2n outputs a signal w12a-2n indicating “1”.

The /WE signal, the signal w12a-21 output from the ENOR circuit 12a-21, and the signal w12a-2n output from the ENOR circuit 12a-2n are input to the AND circuit 12a-3. When all of the input signals indicate “1”, the AND circuit 12a-3 outputs a control signal IH. Thus, when the /WE signal in the current cycle indicates “read” and the row addresses read in the current cycle and the previous cycle are the same, the AND circuit 12a-3 outputs a control signal IH indicating “1”, and when the input signals have any other combination, the AND circuit 12a-3 outputs a control signal IH indicating “0”.

FIG. 3 is a diagram illustrating a specific example of a row address decoder. A row address decoder 14a illustrated in FIG. 3 corresponds to the row address decoder 14 illustrated in FIG. 1. The row address decoder 14a includes an inverter circuit 14a-1, first inverter circuits 14a-11 to 14a-1n, second inverter circuits 14a-21 to 14a-2n, first logic circuits 14a-31 to 14a-3n, and second logic circuits 14a-41 to 14a-4n. As illustrated in FIG. 3, each of the first and second logic circuits has a configuration in which a NAND (Not AND) circuit and an inverter circuit are connected in series.

Address signal lines w13a-1 to w13a-i are i-bit-width address signal lines. The row address decoder 14a uses i-bit row address signals, received through i signal lines w13a-1 to w13a-i, to activate one of n word lines w14 (n is 2ⁱ). The first inverter circuits 14a-11 to 14a-1i invert the logics of row address signals received from the signal lines w13a-1 to w13a-i, respectively. The first inverter circuits 14a-11 to 14a-1i supply the inverted row address signals to the second inverter circuits 14a-21 to 14a-2i and also output the inverted row address signals to the first logic circuits 14a-32 to 14a-3n, respectively. The second inverter circuits 14a-21 to 14a-2i invert the logics of the received row address signals and output the inverted row address signals to the first logic circuits 14a-31 to 14a-(3n−1), respectively. Each of the first logic circuits 14a-31 to 14a-3n output a logical AND of the input signals to the corresponding one of the second logic circuits 14a-41 to 14a-4n. The address signals are externally generated so that, during one cycle of a decoder clock (decck), the output of only one of the first logic circuits 14a-31 to 14a-3n is activated. Each of the second logic circuits 14a-41 to 14a-4n outputs a logical AND of input signals. One of the input signals of each of the second logic circuits 14a-41 to 14a-4n is the decoder clock (decck). Thus, the second logic circuits 14a-41 to 14a-4n transmit output signals in accordance with the pulse period of the decoder clock (decck), respectively. One of the input signals of each of the second logic circuits 14a-41 to 14a-4n is the control signal IH whose logic was inverted by the inverter circuit 14a-1. Thus, when the comparator 12 activates the control signal IH, the second logic circuits 14a-41 to 14a-4n do not transmit the output signals. The outputs of the second logic circuits 14a-41 to 14a-4n are connected to the corresponding word lines of the memory cell array 20. When the output of the second logic circuit is activated, the word line of the memory cell to which the output is to be performed is also activated.

FIG. 4 is a diagram illustrating a specific example of a column address decoder. A column address decoder 16a illustrated in FIG. 4 corresponds to the column address decoder 16 illustrated in FIG. 1. Signal lines w16a-1 to w16a-j are j-bit-width address signal lines. The column address decoder 16 uses j-bit column address signals, received through the signal lines w16a-1 to w16a-j, to activate the CAS signal for one of m CAS signal lines w16 (m is 2^{j}). The column address decoder 16a includes an inverter circuit 16a-1, first inverter circuits 16a-11 to 16a-1n, second inverter circuits 16a-21 to 16a-2n, first logic circuits 16a-31 to 16a-3n, and second logic circuits 16a-41 to 16a-4n. As illustrated in FIG. 4, each of the first and second logic circuits has a configuration in which a NAND circuit and an inverter circuit are connected in series.

The first inverter circuits 16a-11 to 16a-1j invert the logics of column address signals received from the signal lines w16a-1 to w16a-j, respectively. The first inverter circuits 16a-11 to 16a-1j supply the inverted column address signals to the second inverter circuits 16a-21 to 16a-2j and also output the inverted column address signals to the first logic circuits 16a-31 to 16a-(3m−1), respectively. The second inverter circuits 16a-21 to 16a-2j invert the logics of the received column address signals and output the inverted column address signals to the first logic circuits 16a-32 to 16a-3m, respectively. Each of the first logic circuits 16a-31 to 16a-3m outputs a logical AND of the input signals to the corresponding one of the second logic circuits 16a-41 to 16a-4m. The address signals are externally transmitted so that the output of one of the first logic circuits 16a-31 to 16a-3m is activated. Each of the second logic circuits 16a-41 to 16a-4m outputs a logical AND of input signals. One of the input signals of each the second logic circuits 16a-41 to 16a-4m is the decoder clock (decck). Thus, each of the second logic circuits 16a-41 to 16a-4m transmits an output signal in accordance with the pulse period of the decoder clock (decck). Each of the second logic circuits 16a-41 to 16a-4m outputs the column address select (CAS) signal to the multiplexer 25, which is used to select the read latches described below.

FIG. 5A is a diagram illustrating one example of a memory cell used for an SRAM. A memory cell 20a-1 has a flip-flop circuit including six transistors Tr1a to Tr6a. The bit lines blt and blc are precharged to “1” by the bit-line precharge circuit 21. A circuit constituted by the p-type transistor Tr3a and the n-type transistor Tr4a and a circuit constituted by the p-type transistor Tr5a and the n-type transistor Tr6a are provided as inverter circuits. Thus, a potential held at the source terminal of the n-type transistor Tr4a or a potential held at the source terminal of the n-type transistor Tr6a is maintained. In an operation for performing reading from the memory cell 20a-1, the row address decoder 14 first applies a voltage to the word line connected to the gate terminals of the n-type transistors Tr1a and Tr2a. When the n-type transistors Tr1a and Tr2a are turned on, current flows toward the transistor held at “0” to thereby reduce the potential of one of the bit lines blt and blc. As described below with reference to FIG. 7, the sense amplifier 22 detects a reduction in the potential of one of the bit lines blt and blc and reads data from the memory cell to the read latch 24.

FIG. 5B is a diagram illustrating one example of a memory cell. A memory cell 20b-1 illustrated in FIG. 5B is used for a DRAM. The memory cell 20b-1 has an n-type transistor Tr1b and a capacitor C1. The bit lines blt and blc are precharged to “1” by the bit-line precharge circuit 21. In a read operation for the memory cell 20b-1, the row address decoder 14 first applies a voltage to the word line. When the gate terminal of the n-type transistor Tr1b is open, the potential of the bit line blt decreases. Since nothing is connected to the bit line blc, the potential of the bit line blc does not change. When the capacitor C1 has a high potential indicating “1”, the potential difference between the bit line blt and the bit line blc is small. On the other hand, when the capacitor C1 has a low potential indicating “0”, the potential difference between the bit line blt and the bit line blc is large. The sense amplifier 22 amplifies the difference between the potential of the bit line blt and the potential of the bit line blc, so that information stored in the memory cell 20b-1 is read. Data read by the sense amplifier 22 is held by the read latch 24.

FIG. 6 illustrates a specific example of a bit-line precharge circuit. A bit-line precharge circuit 21a illustrated in FIG. 6 is, of the bit-line precharge circuits 21 illustrated in FIG. 1, a portion for pre-charging a pair of bit lines blt and blc. That is, the bit-line precharge circuit 21a precharges the pair of bit lines blt and blc to “1” in accordance with the decoder clock (decck).

FIG. 7 is a diagram illustrating a specific example of a sense amplifier. A sense amplifier 22a illustrated in FIG. 7 is, of the sense amplifier 22 illustrated in FIG. 1, a portion for amplifying the voltage level of one pair of bit lines blt and blc. The sense amplifier 22a has an N-type transistor 22a-1, a latch circuit 22a-2, and inverters 22a-3 and 22a-4. Upon activation of a sense amplifier enable clock (saeck), the latch circuit 22a-2 is operated to amplify the signal of the bit line blt or blc to thereby drive the inverter 22a-3 or 22a-4. In this manner, the sense amplifier 22a reads data (saout) from the memory cell array 20.

FIG. 8 illustrates a specific example of a memory circuit. A read latch 24a illustrated in FIG. 8 holds the data (saout) read from one pair of bit lines blt and blc of the read latch 24 illustrated in FIG. 1. The read latch 24a has inverter circuits 24a-1 to 24a-4 and a transmission gate 24a-5. The inverter circuits 24a-3 and 24a-4 function as a sequence circuit 24a-6. When a latch clock and a latch clock having a logic inverted by the inverter circuit 24a-1 are input to the gate terminals of the transmission gate 24a-5, data having a logic inverted by the inverter circuit 24a-2 is input to the sequence circuit 24a-6 through the transmission gate 24a-5. In the sequence circuit 24a-6, the inverter circuit 24a-3 inverts the logic of the received data and outputs the read data (RD).

FIG. 9 illustrates a specific example of a multiplexer. A multiplexer 25a illustrated in FIG. 9 corresponds to the multiplexer 25 illustrated in FIG. 1. The multiplexer 25a has inverter circuits 25a-1a to 25a-na, transmission gates 25a-1b to 25a-nb, and an inverter 25a-1c. These circuit elements constitute a data output of the corresponding memory circuits and selection circuits 25a-1 to 25a-n, which are connected to outputs of the column select signals. For example, when the CAS signal is supplied to the selection circuit 25a-1, the column select signal and a column select signal having a logic inverted by the inverter circuit 25a-1a are supplied to the gate terminals of the transmission gate 25a-1b. When the signals are supplied to the gate terminals, the RD signal read from the memory circuit is output from the drain of the transmission gate 25a-1b to the inverter 25a-1c. The inverter 25a-1c inverts the logic of the read data and outputs the resulting read data. Thus, the multiplexer 25a may select and read the data stored in the read latch 24, in accordance with the CAS signal.

As described above, when the row address signal in the previous cycle and the row address signal in the current cycle match each other and the /WE signal indicates the read mode “1”, the comparator 12 supplies the control signal IH to the row address decoder 14 to stop the word-line activation performed by the row address decoder 14. Since the data read in the previous cycle is stored in the read latch 24, reading the data stored in the read latch 24 allows the semiconductor memory device 10 to read the data stored in the memory cell array 20 without causing the row address decoder 14 to operate. Thus, the semiconductor memory device 10 may reduce power consumed during data reading, without activating the word lines during the reading.

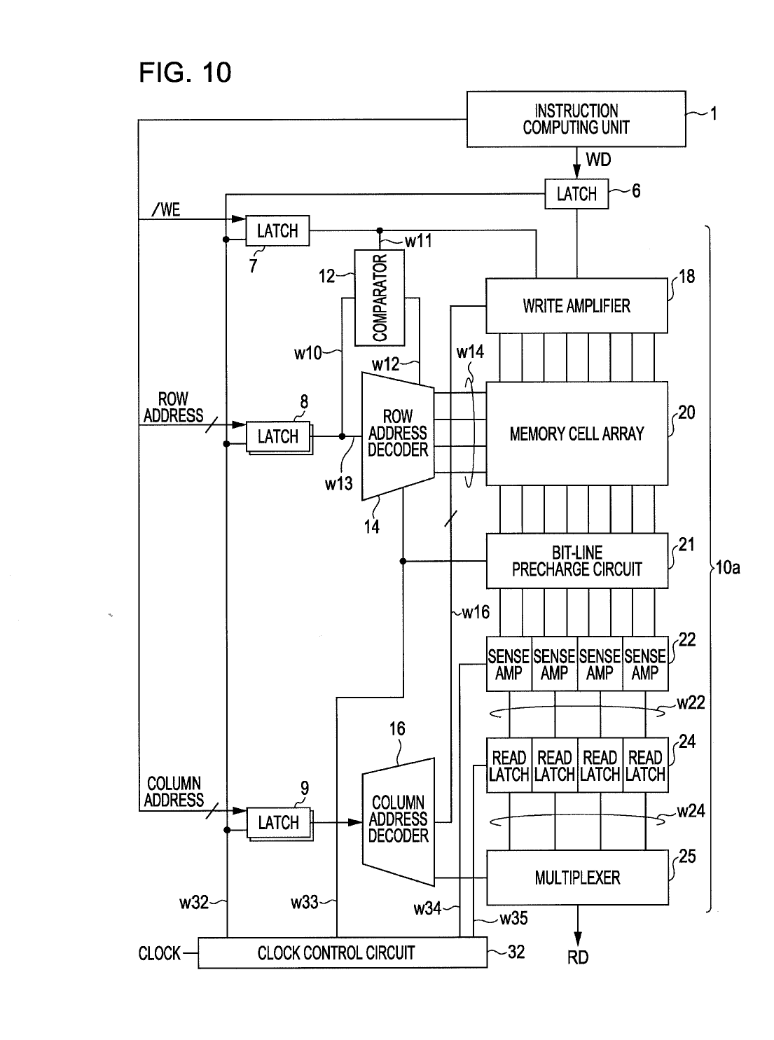

FIG. 10 illustrates one example of a semiconductor memory device. A semiconductor memory device 10a illustrated in FIG. 10 has latch circuits 6 to 9, a write amplifier 18, and a clock control circuit 32 in addition to the elements included in the semiconductor memory device 10 illustrated in FIG. 1. An instruction computing unit 1 is provided external to the semiconductor memory device 10a to supply an address signal, a /WE signal, and a write data (WD) signal to the semiconductor memory device 10a. The instruction computing unit 1 and the semiconductor memory device 10a constitute a computation processing device. The circuit elements of the semiconductor memory device 10a which are the same as those of the semiconductor memory device 10 are not described hereinafter.

The clock control circuit 32 receives an externally supplied clock signal and uses the clock signal to generate a latch clock (latchck), a decoder clock (decck), and a sense amplifier enable clock (saeck). The clock control circuit 32 supplies the latch clock (latchck) to the latch circuits 6 to 9, supplies the decoder clock (decck) to the row address decoder 14, and supplies the sense amplifier enable clock (saeck) to the sense amplifier 22. The clock control circuit 32 outputs those clock signals to the elements in the semiconductor memory device 10a, as described above, to allow the elements in the semiconductor memory device 10a to operate in synchronization with the clocks.

The latch circuits 6 to 9 serve as circuits that store the clocks for a predetermined period in order to cause the elements in the semiconductor memory device 10a to operate synchronously.

The write amplifier 18 serves as a circuit for writing, when the /WE signal indicates “0”, the write data (WD) signal to the memory cell specified by the word line and the bit line indicated by the CAS signal. The write amplifier 18 receives the WD signal from the instruction computing unit 1 and receives the CAS signal, output from the column address decoder 16, through the signal line w16. The write amplifier 18 then activates the bit line blt or blc corresponding to the CAS signal.

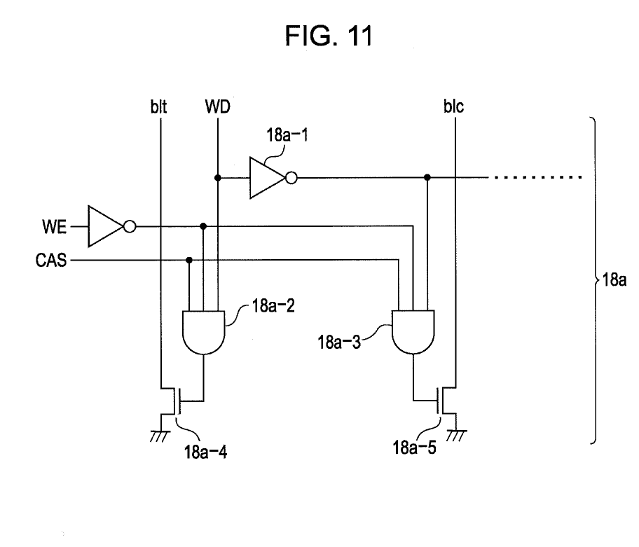

FIG. 11 is a specific example of a write amplifier. A write amplifier 18a illustrated in FIG. 11 is, of the write amplifier 18 illustrated in FIG. 10, a portion for driving one pair of bit lines blt and blc. The write amplifier 18a has an inverter circuit 18a-1, AND circuits 18a-2 and 18a-3, and transistors 18a-4 and 18a-5.

The inverter circuit 18a-1 inverts the externally supplied WD signal and outputs the inverted WD signal to the AND circuit 18a-3. The AND circuit 18a-2 receives the /WE signal, the CAS signal output from the column address decoder 16, and the externally supplied WD signal, and outputs a logical AND of all of the signals. The AND circuit 18a-3 receives the CAS signal and the WD signal inverted by the inverter 18a-1 and outputs a logical AND of both of the signals. The outputs of the AND circuits 18a-2 and 18a-3 are supplied to gate terminals of the transistors 18a-4 and 18a-5, respectively. Since the input and the output of the inverter 18a-1 are connected to inputs of the AND circuits 18a-2 and 18a-3, respectively, one of the bit lines blt and blc is discharged to “0” in accordance with the signal level of the WD signal.

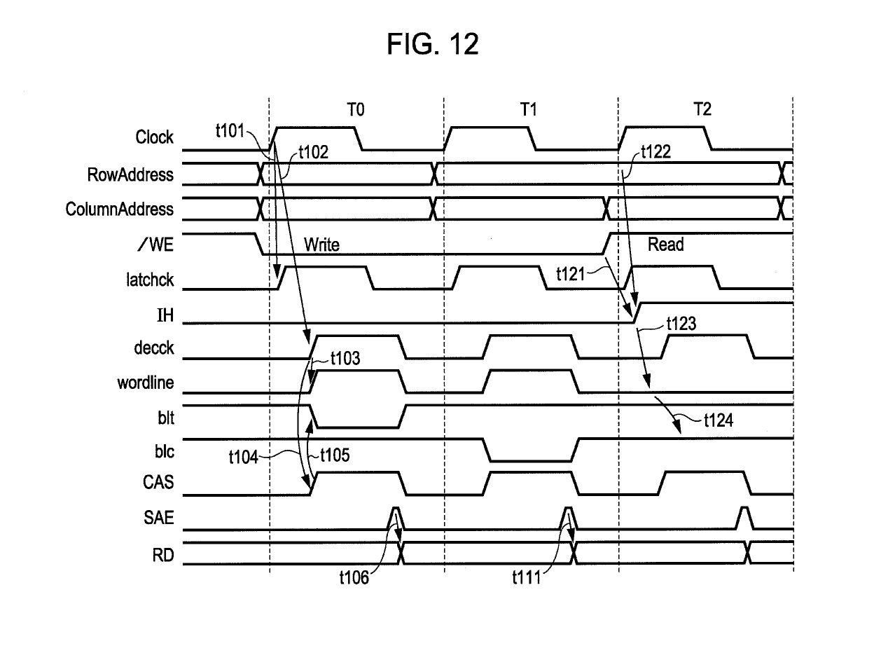

FIG. 12 illustrates one example of a timing chart of signals received by or supplied to the semiconductor memory device 10a. The externally supplied clock signal (Clock), a row address signal (RowAddress), a column address signal (ColumnAddress), and the /WE signal are input to the semiconductor memory device 10a. The row address signal (RowAddress), the column address signal (ColumnAddress), and the RD signal are multi-bit-width signals.

In the period of time T0, upon input of the clock signal (Clock), the clock control circuit 32 generates the latch clock (latchck), as indicated by t101, and generates and outputs the decoder clock (decck), as indicated by t102. The row address decoder 14 decodes the row addresses and activates the word line (wordline). The column address decoder 16 decodes the column addresses and activates the CAS signal in synchronization with the decoder clock (decck), as indicated by t104. The logical AND of the CAS signal and the /WE signal holds true, the write amplifier 18 drives the bit line blt to “0”, as indicated by t105, to write data to the memory cell specified by the word line and the bit line blt.

Upon input of the clock signal, the clock control circuit 32 generates and outputs a sense amplifier enable (SAE) signal. Upon input of the SAE signal, the sense amplifier 22 reads data from the memory cell to which the data was written by the write amplifier 18 at t105, as indicated by t106, so that the read data is stored in the read latch 24.

In the period of time T1, the /WE signal is “0” indicating the write mode, as in the period of time T0. Thus, as in the period of time T0, an operation for writing the WD signal to the memory cell specified by the row address and the column address is performed, and simultaneously, the sense amplifier 22 reads data from the memory cell and stores the read data in the read latch 24, as indicated by t111.

In the period of time T2, the /WE signal is “1” indicating the read mode. The row addresses in the periods of time T1 and T2 are the same. Thus, the comparator 12 activates the control signal IH as indicated by t121 and t122, so that the word-line level change at the row address decoder 14 is suppressed, as indicated by t123. That is, the level of the word line is constant and thus, even when the sense amplifier 22 operates, no data is read from the memory cell, as indicated by t124.

Thus, when the row addresses in the previous cycle and the subsequent cycle match each other, the semiconductor memory device 10a reads data, held in the period of the previous cycle, from the memory circuit, to thereby read data from the memory cell, without activating the word line. Thus, since a change in the level of the word line is suppressed, the semiconductor memory device 10a may reduce the power consumed during reading. Thus, even when the mode in the previous cycle is the write mode, the semiconductor memory device 10a simultaneously holds the data, written to the memory cell in the write mode, in the memory circuit. Thus, even when the mode in the previous cycle is the write mode and the mode in the current cycle is the read mode, the data held in the period of the previous cycle is read from the memory circuit to thereby make it possible to suppress power consumed by word-line activation.

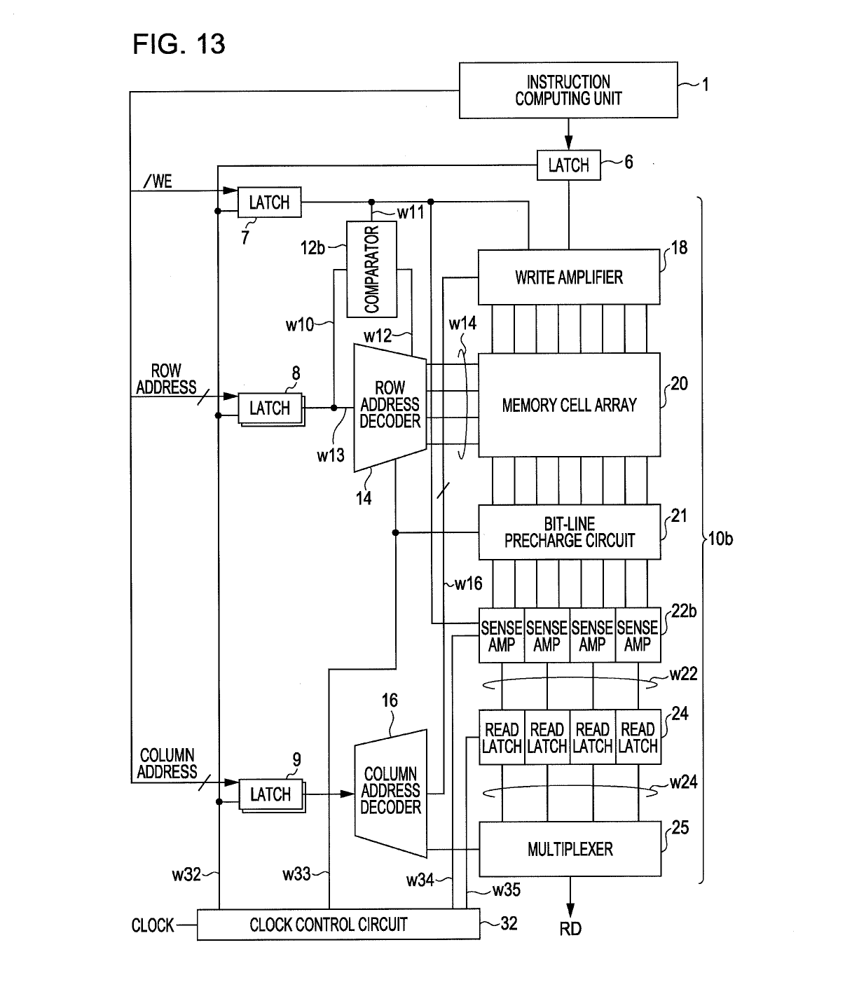

FIG. 13 illustrates one example of a semiconductor memory device. Compared to the semiconductor memory device 10a illustrated in FIG. 10, a semiconductor memory device 10b illustrated in FIG. 13 is different in a comparator 12b and a sense amplifier 22b. Since other elements included in the semiconductor memory device 10b are the same as those in the semiconductor memory device 10a, descriptions thereof are not given hereinafter.

In the comparator 12b, a condition of continuous read access to the memory cell in the previous and current cycles is added to the inputs of the AND circuit that is included in the above-described comparator 12 and that outputs the control signal IH. When the sense amplifier 22b receives the /WE signal and the received /WE signal indicates the write mode, the sense amplifier 22b does not output the control signal IH.

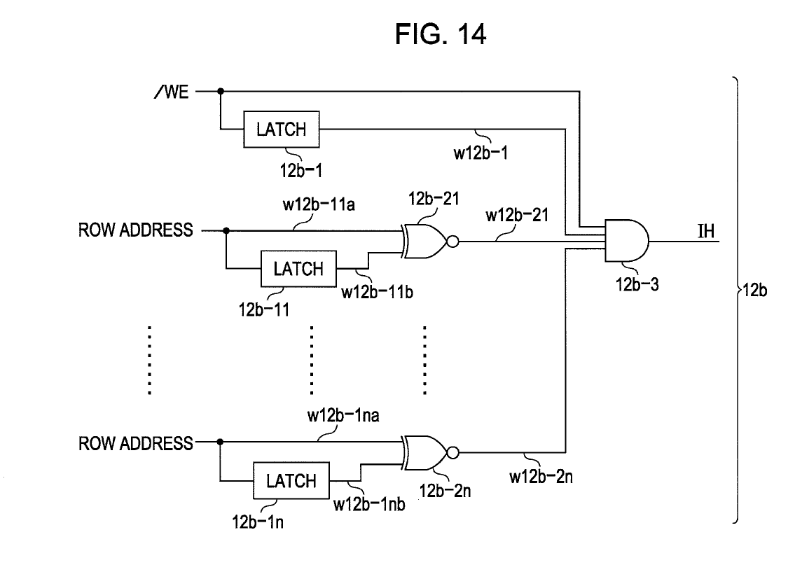

FIG. 14 illustrates a specific example of the comparator 12b. Compared to the comparator 12a illustrated in FIG. 2, the comparator 12b further has a latch circuit 12b-1. The /WE signal, a signal w12b-1 output from a latch circuit 12b-1, a signal w12b-21 output from an ENOR circuit 12b-21, and a signal w12b-2n output from an ENOR circuit 12b-2n are input to an AND circuit 12b-3. When the output of the latch circuit 12b-1 is “1”, it means that the /WE signal in the previous cycle was the read mode. When all of the input signals indicate “1”, the AND circuit 12b-3 outputs a control signal IH. Thus, when the /WE signals in the previous and current cycles indicate the read mode and the row addresses read in the previous and current cycles are the same, the AND circuit 12b-3 activates the control signal IH. Since the comparator 12a according to the first embodiment described above does not compare the /WE signals in the previous and current cycles, the comparator 12a outputs the control signal IH even when the /WE signal in the previous cycle is the write mode. The comparator 12b, however, does not output the control signal IH when the /WE signal in the previous cycle indicates the write mode.

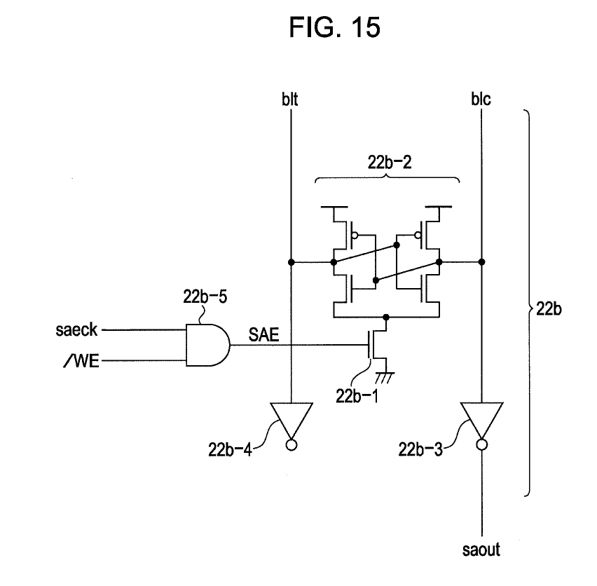

FIG. 15 illustrates a specific example of the sense amplifier 22b. The sense amplifier 22b is different from the sense amplifier 22a according to the first embodiment in that an AND circuit 22b-5 is added. The AND circuit 22b-5 receives the sense-amplifier enable signal clock (saeck) and the /WE signal and outputs a sense amplifier enable (SAE) signal. Consequently, when the /WE signal is “1” indicating the read mode, the sense amplifier 22b reads data from the memory cell and when the /WE signal indicates the write mode, the sense amplifier 22b does not read data from the memory cell.

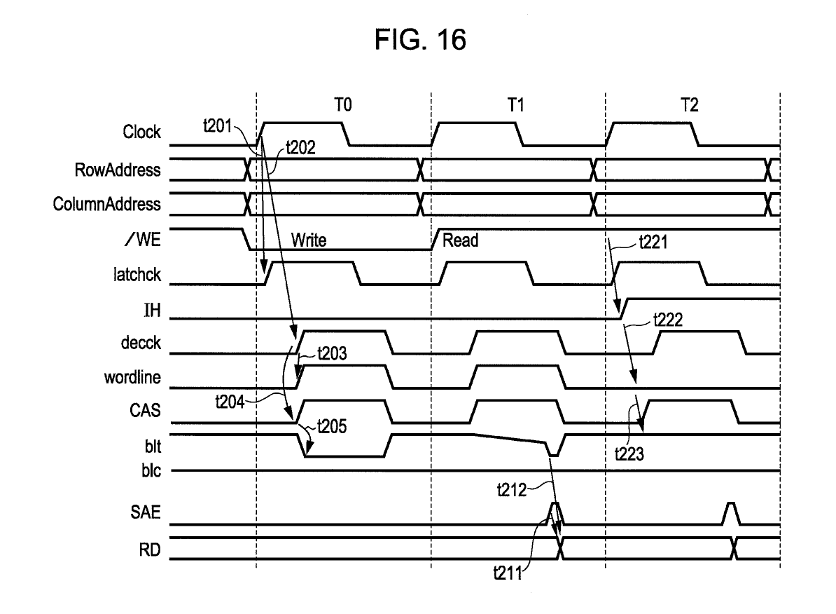

FIG. 16 illustrates one example of a timing chart of signals received by or supplied to the semiconductor memory device 10b. The externally supplied clock signal (Clock), the row address signal (RowAddress), the column address signal (ColumnAddress), and the /WE signal are input to the semiconductor memory device 10b. The row address signal (RowAddress), the column address signal (ColumnAddress), and the RD signal are multi-bit-width signals.

In the period of time T0, the /WE signal in the cycle T0 indicates the write mode. Thus, the comparator 12b does not activate the control signal IH. Upon input of the clock signal (Clock), the clock control circuit 32 generates a latch clock (latchck), as indicated by t201, and generates and outputs a decoder clock (decck), as indicated by t202. The row address decoder 14 decodes the column addresses and activates the word line (wordline) in synchronization with the decoder clock (decck), as indicated by t203. The column address decoder 16 decodes the column addresses and activates the CAS signal in synchronization with the decoder clock (decck), as indicated by t204. The /WE signal is “0” indicating the write mode. Thus, the output of the logical AND of the CAS signal and the /WE signal becomes “1”, so that the write amplifier 18 drives the bit line bit to “0”, as indicated by t205, to write a bit to the memory cell specified by the word line and the bit line bit. Since the sense amplifier 22b activates the SAE signal when the /WE signal is “1” indicating the read mode, the level of the SAE signal does not change in the period of time T0 in which the /WE signal is “0”.

In the period of time T1, the /WE signal is “1” indicating the read mode. However, since the /WE signal in the cycle T0 and the /WE signal in the cycle T1 are different from each other, the comparator 12b does not activate the control signal IH. On the other hand, since the SAE signal is activated in the read mode in which the /WE signal is “1”, the SAE signal is activated in the period of time T1 in which the /WE signal is “1”, as indicated by t211. The sense amplifier 22b then reads data from the memory cell specified by the word line and the bit line, as indicated by t212, and stores the read data (RD) in the read latch 24.

In the period of time T1, when the mode in the previous cycle T0 is the write mode, the sense amplifier 22b does not operate in the period of the previous cycle T0 and thus the read latch 24 does not store data read in the previous cycle T0. When the mode in the previous cycle is the write mode, the comparator 12b does not supply the control signal IH even when the row addresses in the previous and current cycles are the same. Thus, the row address decoder 14 changes the level of the word line in the period of the current cycle to read data from the memory cell.

In the period of time T2, the /WE signal indicates the read mode “1”, which is the same as in the period of time T1 in the previous cycle. The row addresses in the periods of time T1 and T2 are the same. Thus, the comparator 12b activates the control signal IH, as indicated by t221. Since the control signal IH is activated, the row address decoder 14 suppresses a change in the level of the word line, as indicated by t222. Since the level change in the word line is suppressed, no data is read from the memory cell (see RD), as indicated by t223, even when the sense amplifier 22 operates.

As described above, in the semiconductor memory device 10b, when the mode in the previous cycle is the write mode and the mode in the current cycle is the read mode, the control signal IH is not output. Since a change in the level of the word line in the semiconductor memory device 10a according to the second embodiment described above is suppressed when the selected row addresses match each other, the semiconductor memory device 10b according to the third embodiment has a smaller word-line-activation power consumption effect than the semiconductor memory device 10a. Compared to the semiconductor memory device 10a, the semiconductor memory device 10b also has a power consumption effect in that the sense amplifier 22b does not operate in the write mode.

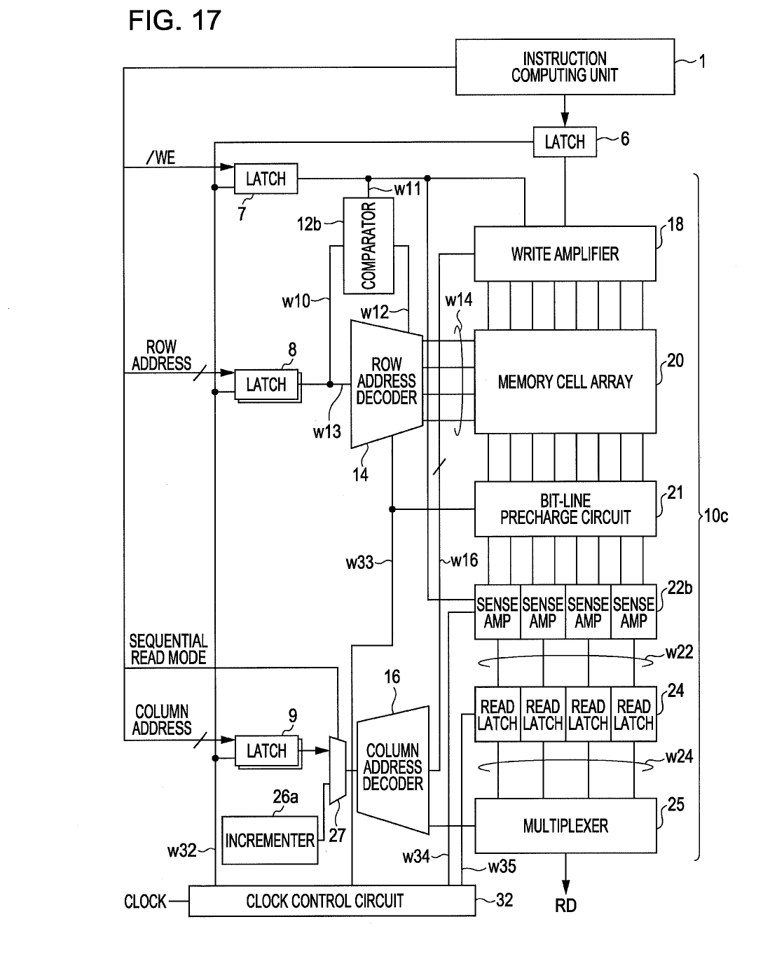

A semiconductor memory device 10c illustrated in FIG. 17 has an incrementer 26a and a selection circuit 27 in addition to the above-described semiconductor memory device 10b. The semiconductor memory device 10c has a sequential read mode terminal (not illustrated). When a sequential read mode signal is activated, the semiconductor memory device 10c performs a read operation on memory cells in multiple columns at the same row address. The sequential read mode terminal serves to receive the sequential read signal from the instruction computing unit 1. The sequential read mode refers to an operation for performing sequential reading on the memory cells in the column direction. For reading data from the memory cell for each address, the semiconductor memory device 10b described above receives multiple read instructions from the instruction computing unit 1 to read the data from continuous column addresses at the same row address. In contrast, in the case of the sequential read mode, the semiconductor memory device 10c may read data from continuous column addresses at the same row address by receiving a single read instruction from the instruction computing unit 1. Thus, the number of read-instruction receptions from the instruction computing unit 1 decreases, so that the total amount of time of the reading processing in the sequential read mode is smaller. The incrementer 26a serves as a circuit for sequentially outputting a column address. When the sequential mode signal is activated, the selection circuit 27 selects the signal output from the incrementer 26a and does not select the column address output from the latch circuit 9.

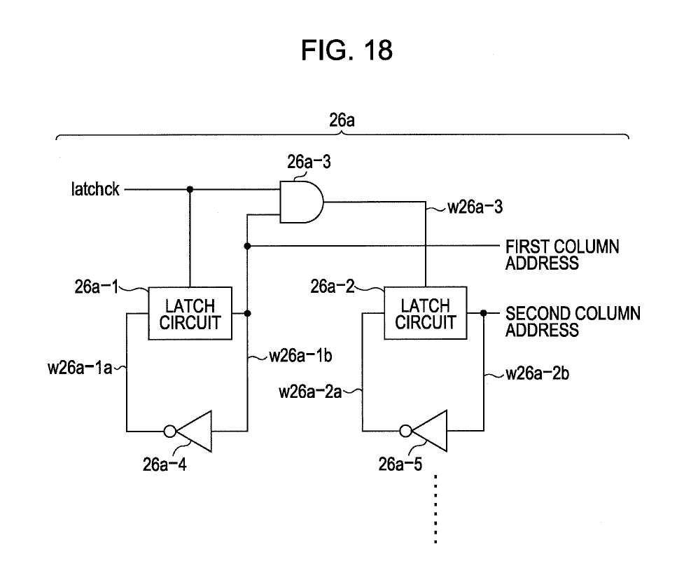

FIG. 18 illustrates a specific example of the incrementer 26a. The incrementer 26a has latch circuits 26a-1 and 26a-2, an AND circuit 26a-3, and inverter circuits 26a-4 and 26a-5. Although FIG. 18 illustrates only two latch circuits for description, the number of latch circuits included in the incrementer 26a is the same as the number of column addresses. For example, the latch circuits 26a-1 and 26a-2 may have the same configuration as the latch circuit illustrated in FIG. 8. The latch circuit 26a-1 receives the latch clock (latchck) and a signal w26a-1a and holds an input value of the signal w26a-1a for only one cycle of the latch clock. The signal w26a-1a and the latch clock are input to the AND circuit 26a-3. Although only one AND circuit 26a-3 is illustrated for description, latch circuits other than the latch circuit 26a-1 also have AND circuits at their inputs. Each AND circuit determines a logical AND of the latch clock and the output signal of the corresponding latch circuit.

The latch circuit 26a-1 and 26a-2 are set to have, for example, an initial value “0” by using resistors. In an initial cycle T0, the latch circuit 26a-1 outputs the held initial value “0” to a signal line w26a-1b. The latch circuit 26a-1 outputs the output value of the signal line w26a-1b to the selection circuit 27 as a first column address. The latch circuit 26a-2 outputs the initial value “0” to the selection circuit 27 as a second column address. A signal “1” obtained by inversion performed by the inverter circuit 26a-4 is input to the latch circuit 26a-1. Thus, in the period of the cycle T0, the first column address becomes “0” and the second column address becomes “0”, respectively.

In the period of a next cycle T1, the latch circuit 26a-1 selects “1” as the first column address and outputs it to the selection circuit 27. Since the input signal w26a-1b is activated, an output w26a-3 of the AND circuit 26a-3 is also activated. Since the output of the AND circuit 26a-3 is not activated in the previous cycle T0, the latch circuit 26a-2 outputs the initial value “0” to the selection circuit 27 as the second column address. A signal “1” obtained by inversion performed by the inverter circuit 26a-5 is input to the latch circuit 26a-2. Thus, in the cycle T1, the first column address becomes “1” and the second column address becomes “0”.

In the period of a next cycle T2, the latch circuit 26a-1 outputs “0” to the signal line w26a-1b. Since the output of the AND circuit 26a-3 is activated in the previous cycle T1, the latch circuit 26a-2 outputs “1”. Thus, in the cycle T2, the first column address becomes “0” and the second column address becomes “1”.

In the period of a next cycle T3, the latch circuit 26a-1 outputs “1” to the signal line w26a-1b. Since the output of the AND circuit 26a-3 was not activated in the previous cycle T2, the latch circuit 26a-2 outputs “0”. Thus, in the cycle T3, the first column address becomes “1” and the second column address becomes “0”. In this manner, the incrementer 26a increments the column addresses.

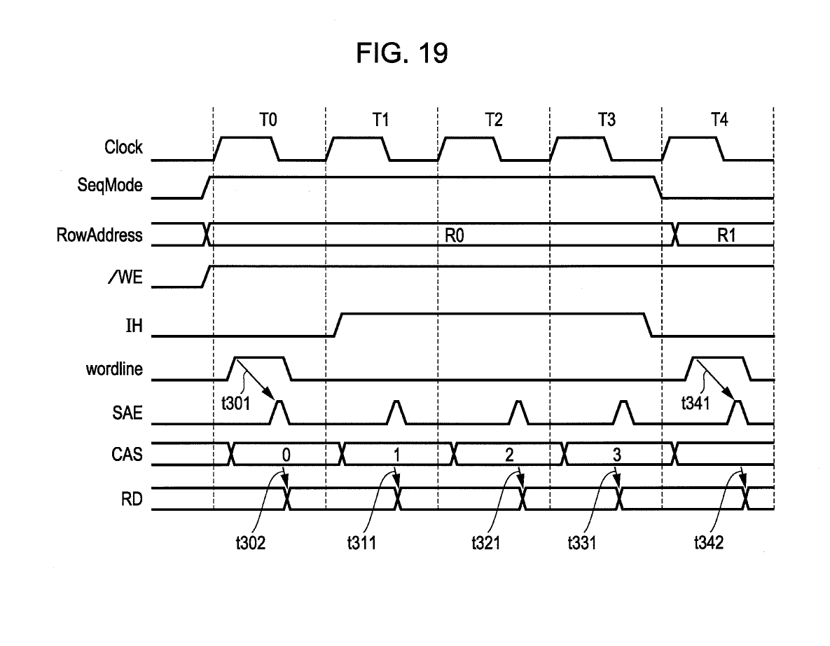

FIG. 19 illustrates one example of a timing chart of signals received by or supplied to the semiconductor memory device 10c. The semiconductor memory device 10c receives or supplies externally supplied clock signal (Clock), a sequential read mode signal (SeqMode), a row address signal (RowAddress), a /WE signal, a control signal (IH), a word line (wordline), an SAE signal, a CAS signal, and an RD signal. The row address signal (RowAddress), the CAS signal, and the RD signal are multi-bit-width signals.

In the period of time T0, the sequential mode signal (SeqMode) is activated. The /WE signal is “1” indicating the read mode. Thus, as indicated by t301, the semiconductor memory device 10c reads data from all memory cells provided along one word line and stores the read data in the read latch 24. The multiplexer 25 reads the read data RD from the read latch 24, as indicated by t302.

In the period of time T1, the sequential mode signal (SeqMode) is activate. The /WE signal indicates the read mode. The row address is R0, which is the same as the row address in the previous cycle T0. Thus, the comparator 12b activates the control signal IH. On the other hand, since the data read from the same-row-address memory cells at the same row address in the period of the cycle T0 are held in the read latch 24, the multiplexer 25 reads the data from the read latch 24 in accordance with the CAS signal incremented by one by the incrementer 26a, as indicated by t311.

In the period of time T2, the sequential mode signal (SeqMode) is activate. The /WE signal indicates the read mode. The row address is R0, which is the same as the row address in the previous cycle T1. Thus, the comparator 12b activates the control signal IH. On the other hand, since the data read from the memory cells at the same row address in the period of the cycle T0 are held in the read latch 24, the multiplexer 25 reads the data RD from the read latch 24 in accordance with the CAS signal incremented by one by the incrementer 26a, as indicated by t321.

In the period of time T3, the sequential mode signal (SeqMode) is activate. The /WE signal indicates the read mode. The row address is R0, which is the same as the row address in the previous cycle T2. Thus, the comparator 12b activates the control signal IH. On the other hand, since the data read from the memory cells at the same row address in the period of the cycle T0 are held in the read latch 24, the multiplexer 25 reads the data from the read latch 24 in accordance with the CAS signal incremented by one by the incrementer 26a, as indicated by t331.

In the period of time T4, the sequential mode signal (SeqMode) is inactive. The /WE signal indicates the read mode. The row address is not R0, which is the row address in the previous cycle T3. Thus, the comparator 12b deactivates the control signal IH. As indicated by t341, the read data RD is read out to the read latch 24 from the memory cell specified by the word line and the bit line. The multiplexer 25 reads the read data RD from the read latch 24, as indicated by t342.

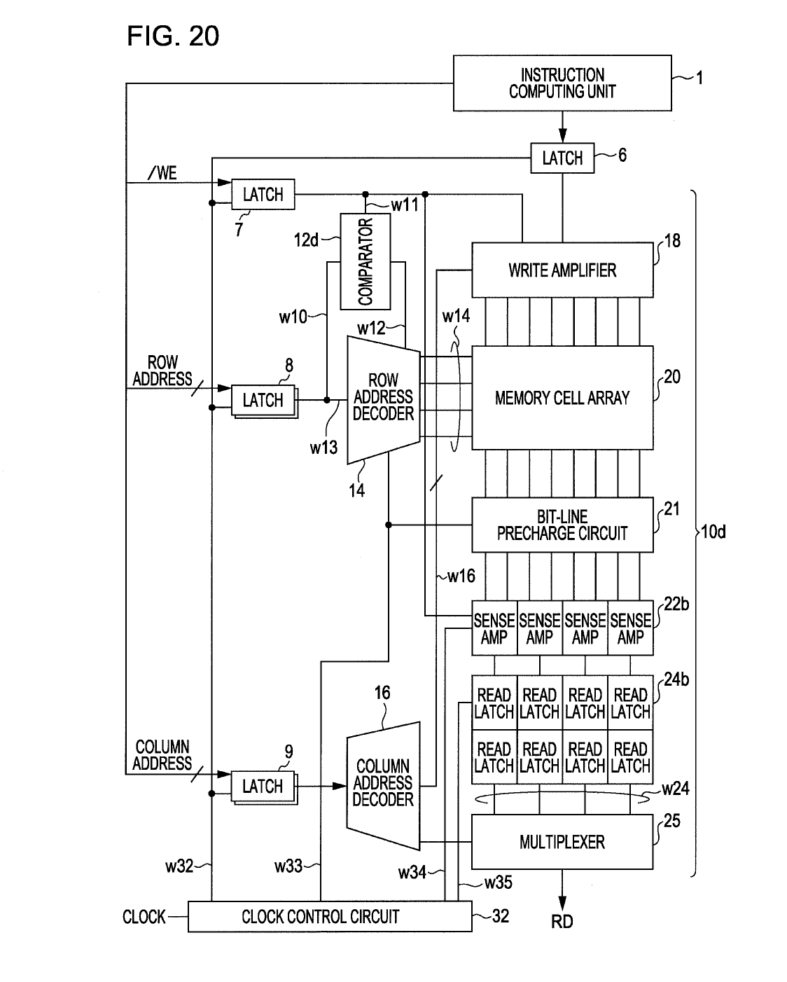

Compared to the semiconductor memory device 10a, a semiconductor memory device 10d illustrated in FIG. 20 is different in a comparator 12d and a read latch 24d. Since other configurations of the semiconductor memory device 10d are the same as those of the semiconductor memory device 10a, descriptions thereof are not given hereinafter. The comparator 12d compares the /WE signals in the cycle before the previous one, in the previous cycle, and in the current cycle, and also compares the row addresses in the cycle before the previous one, in the previous cycle, and in the current cycle. The read latch 24d has a two-stage memory circuit configuration to hold the read data in the cycle before the previous one. When read operations in the cycle before the previous one, the previous cycle, and the current cycle are performed on the same row address, the semiconductor memory device 10d reads data in the cycle before the previous one or the previous cycle from the read latch 24d. Thus, the data is read without activation of the word line and the driving of the read sense amplifier.

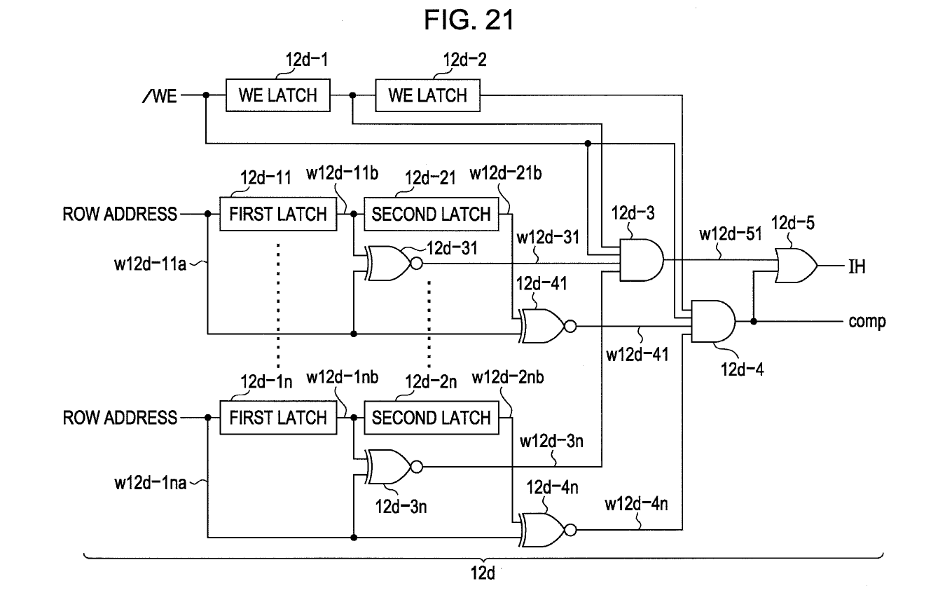

FIG. 21 illustrates a specific example of the comparator 12d. The comparator 12d has WE latch circuits 12d-1 and 12d-2, first latch circuits 12d-11 to 12d-1n, second latch circuits 12d-21 to 12d-2n, first ENOR circuits 12d-31 to 12d-3n, second ENOR circuits 12d-41 to 12d-4n, AND circuits 12d-3 and 12d-4, and an OR circuit 12d-5. The first latch circuits 12d-11 to 12d-1n and the second latch circuits 12d-21 to 12d-2n are provided for the corresponding row addresses. The first ENOR circuits 12d-31 to 12d-3n and the second ENOR 12d-41 to 12d-4n are also prepared for the corresponding row addresses.

When the value of a signal w12d-11b output from the latch 12d-11 that holds a row address in the previous cycle and the value of an input signal w12d-11a of the row address in the current cycle match each other, the first ENOR circuit 12d-31 outputs a signal w12d-31 indicating “1”. Similarly, when the value of a signal w12d-1nb output from the latch 12d-1n that holds a row address in the previous cycle and the value of an input signal w12d-1na of the row address in the current cycle match each other, the first ENOR circuit 12d-3n outputs a signal w12d-3n indicating “1”. In this manner, the first ENOR circuits 12d-31 to 12d-3n determine whether or not the row address in the current cycle and the row address in the previous cycle match each other.

When the value of a signal w12d-21b output from the second latch 12d-21 that holds a row address in the cycle before the previous one and the value of an input signal w12d-11a of the row address in the current cycle match each other, the second ENOR circuit 12d-41 outputs a signal w12d-41 indicating “1”. When the value of a signal w12d-2nb output from the second latch 12d-2n that holds a row address in the cycle before the previous one and the value of the input signal w12d-1na of the row address in the current cycle match each other, the second ENOR circuit 12d-4n outputs a signal w12d-4n indicating “1”. In this manner, the second ENOR circuits 12d-41 to 12d-4n determine whether or not the row address in the current cycle and the row address in the cycle before the previous one match each other.

The /WE signal in the current cycle, the /WE signal in the previous cycle, the output signal w12d-31 of the first ENOR circuit 12d-31, and the output signal w12d-3n of the second ENOR circuit 12d-3n are input to the AND circuit 12d-3. When all of the input signals indicate “1”, the AND circuit 12d-3 activates a signal w12d-51. In this manner, the AND circuit 12d-3 is a circuit for taking a logic as to whether or not the /WE signals in the current and previous cycles indicate the read mode and whether or not the row addresses in the current and previous cycles match each other.

The /WE signal in the current cycle, the /WE signal in the cycle before the previous one, the output signal w12d-41 of the second ENOR circuit 12d-41, and the output signal w12d-4n of the second ENOR circuit 12d-4n are input to the AND circuit 12d-4. When all of the input signals indicate “1”, the AND circuit 12d-4 outputs a signal (comp). Thus, the AND circuit 12d-4 serves as a circuit for taking a logic as to whether or not the /WE signal in the current cycle and the /WE signal in the cycle before the previous one indicate the read mode and whether or not the row address in the current cycle and the row address in the cycle before the previous one match each other.

When any of the input signals indicates “1”, the OR circuit 12d-5 outputs a control signal IH. Thus, the OR circuit 12d-5 outputs the control signal IH when any of the logics of the AND circuits 12d-3 and 12d-4 holds true. As described above with reference to FIG. 3, the control signal IH stops the operation of the row address decoder 14. Thus, according to the semiconductor memory device 10d, when the row addresses in the cycle before the previous one and the current cycle match each other and the /WE signal indicates the read mode or when the row addresses in the previous cycle and the current cycle match each other and the /WE signals indicate the read mode, the level of the word line does not change.

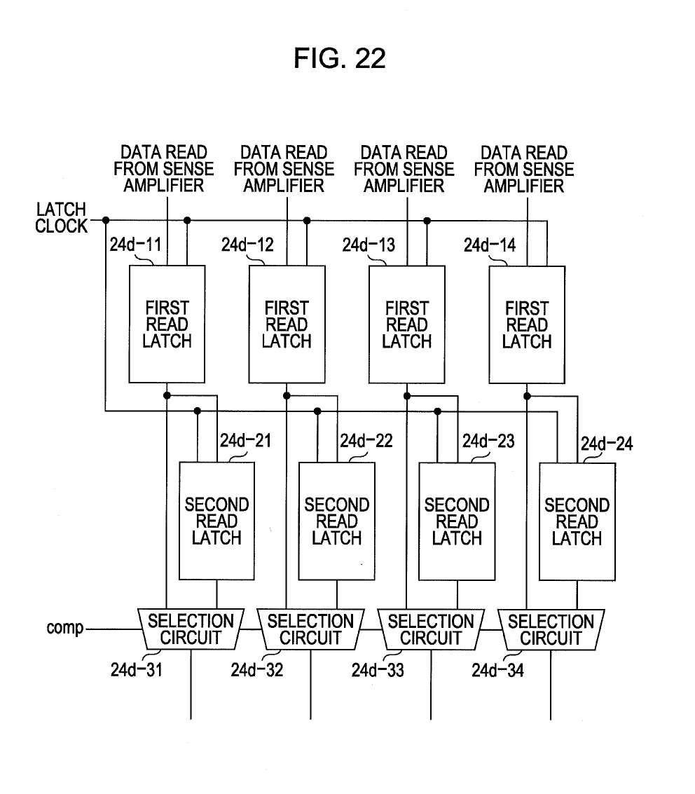

FIG. 22 is a specific example of the read latch 24d. The read latch 24d has first read latches 24d-11 to 24d-14, second read latches 24d-21 to 24d-24, and selection circuits 24d-31 to 24d-34. The first read latches 24d-11 to 24d-14 are latch circuits for storing data read from the sense amplifier 22. The second read latches 24d-21 to 24d-24 are latch circuits for storing data read from the first read latches 24d-11 and 24d-14. Each of the circuit configurations of the first read latches 24d-11 to 24d-14 and the second read latches 24d-21 to 24d-24 may be the same as the configuration of the read latch 24a illustrated in FIG. 8. In accordance with the corresponding latch clock output from the clock control circuit 32, each of the first read latches 24d-11 to 24d-14 operates to receive a read data (RD) signal of the sense amplifier 22 and holds the RD signal as the data RD read from the sense amplifier 22 in the previous cycle. In accordance with the corresponding latch clock output from the clock control circuit 32, each of the second read latches 24d-21 to 24d-24 operates to receive output data of the first read latches 24d-11 to 24d-14, respectively, and holds the output data as the data output from the sense amplifier 22 in the cycle before the previous one.

The output signal (comp) of the comparator 12d is input to the selection circuits 24d-31 to 24d-34. The output signal (comp) is activated when the /WE signal in the current cycle and the /WE signal in the cycle before the previous one indicate the read mode and the row address in the current cycle and the row address in the cycle before the previous one match each other. Thus, when the signal (comp) is activate, the selection circuits 24d-31 to 24d-34 activate output signals of the second read latches 24d-21 to 24d-24, respectively. When the signal (comp) is inactive, the selection circuits 24d-31 to 24d-34 activate output signals of the first read latches 24d-11 to 24d-14, respectively.

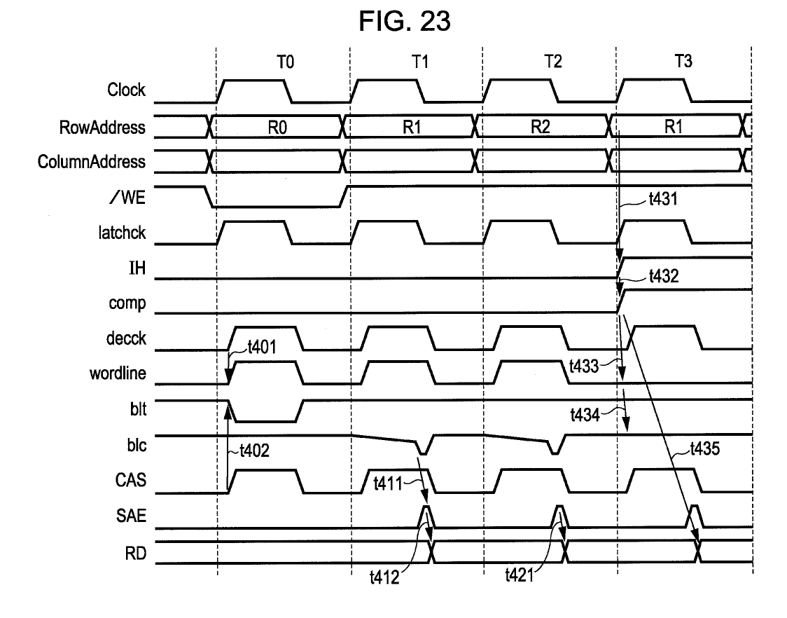

FIG. 23 illustrates one example of a timing chart of signals received by or supplied to the semiconductor memory device 10d. The semiconductor memory device 10d receives or supplies an externally supplied clock signal (Clock), a row address signal (RowAddress), a column address signal (ColumnAddress), a /WE signal, a latch clock (latchck), a control signal IH, a signal (comp), and a decoder clock (decck). The semiconductor memory device 10d further receives or supplies bit lines blt and blc, a CAS signal, an SAE signal, and an RD signal. The row address signal (RowAddress), the column address signal (ColumnAddress), and the RD signal are multi-bit-width signals.

In the period of time T0, since the /WE signal in the cycle T0 indicates the write mode, the comparator 12d does not activate the control signal IH. The row address decoder 14 thus decodes the row addresses and activates the word line (wordline) in synchronization with the decoder clock (decck), as indicated by t401. The column address decoder 16 decodes the column addresses and activates the CAS signal in synchronization with the decoder clock (decck). Since the logical AND of the CAS signal and the /WE signal holds true, the write amplifier 18 drives the bit line blt to “0”, as indicated by t402, to write a bit to the memory cell specified by the word line and the bit line bit. Since the sense amplifier 22b activates the SAE signal when the /WE signal is “1” indicating the read mode, the sense amplifier 22b does not activate the SAE signal in the period of time T0 in which the /WE signal is “0”.

In the period of time T1, the /WE signal is “1” indicating the read mode. However, since the /WE signal in the cycle T0 and the /WE signal in the cycle T1 are different from each other, the comparator 12d does not activate the control signal IH. On the other hand, since the SAE signal is activated in the read mode in which the /WE signal is “1”, the comparator 12d activates the SAE signal in the period of time T1 in which the /WE signal is “1”, as indicated by t411. The sense amplifier 22b then reads data from the memory cell specified by the word line and the bit line, as indicated by t412, and stores the read data (RD) in the read latch 24d.

In the period of time T2, a row address “R1” in the previous cycle T1 is different from a row address “R2” in the current cycle T2. Thus, the comparator 12d does not activate the control signal IH. Thus, the word line is activated, and the sense amplifier 22b reads data from the memory cell specified by the word line and the bit line, as indicated by t421, and stores the read data (RD) in the read latch 24d, as in the period of time T1.

In the period of time T3, the row address “R1” in the cycle T1 before the previous one is the same as a row address “R1” in the current cycle T3. The /WE signal is “1” indicating the read mode. Thus, the comparator 12d activates the control signal IH, as indicated by t431. The /WE signal “1” in the cycle T1 before the previous one and the /WE signal “1” in the current cycle T3 are the same. Thus, the comparator 12d activates the signal (comp), as indicated by t432. Since the control signal IH is activated, the row address decoder 14 does not activate the word line, as indicated by t433. Since the word line is not activated, the bit line is not activated as well, as indicated by t434. Thus, as indicated by t435, the activated signal (comp) causes the read data held in the cycle before the previous one to be read from the read latch 24d.

As described above, according to the semiconductor memory device 10d, data in the cycle before the previous one in addition to the data in the previous cycle is held in the memory circuit, thus making it possible to reduce the number of operations for activating the word lines and reading data from the memory cells and also making it possible to reduce the power consumption.

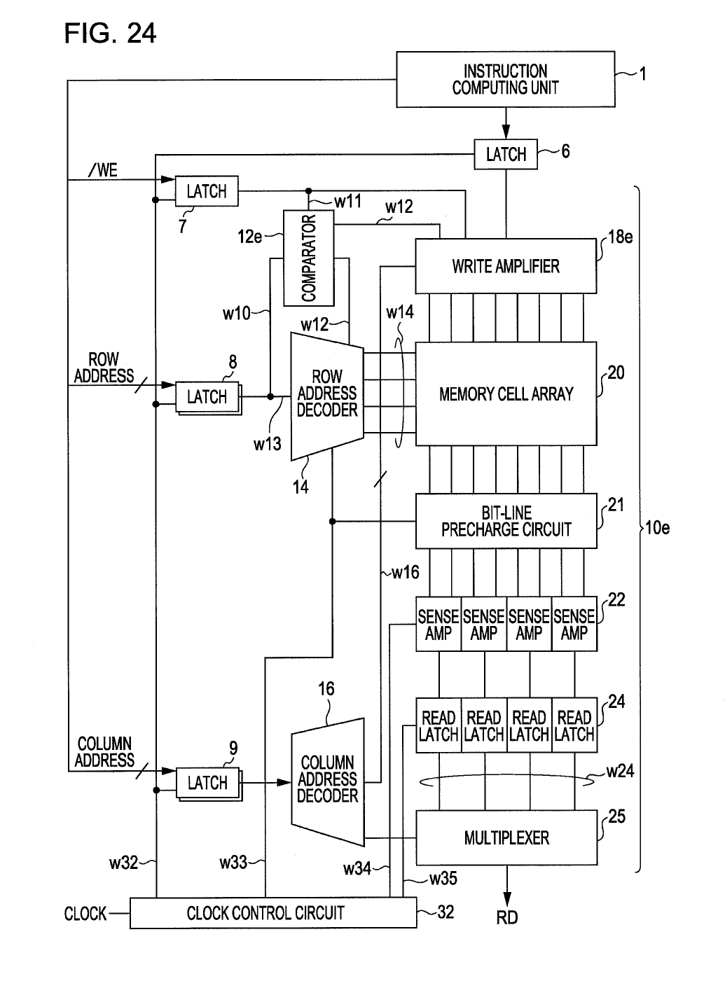

Compared to the semiconductor memory device 10a, a semiconductor memory device 10e illustrated in FIG. 24 is different in a comparator 12e and a write amplifier 18e. Since other configurations of the semiconductor memory device 10e are the same as those of the semiconductor memory device 10a, descriptions thereof are not given hereinafter. When the row address in the previous cycle and the row address in the current cycle match each other, the comparator 12e outputs a signal (comp) for stopping the write operation. Upon input of the signal (comp) output from the comparator 12e, the write amplifier 18e stops activation of the bit lines.

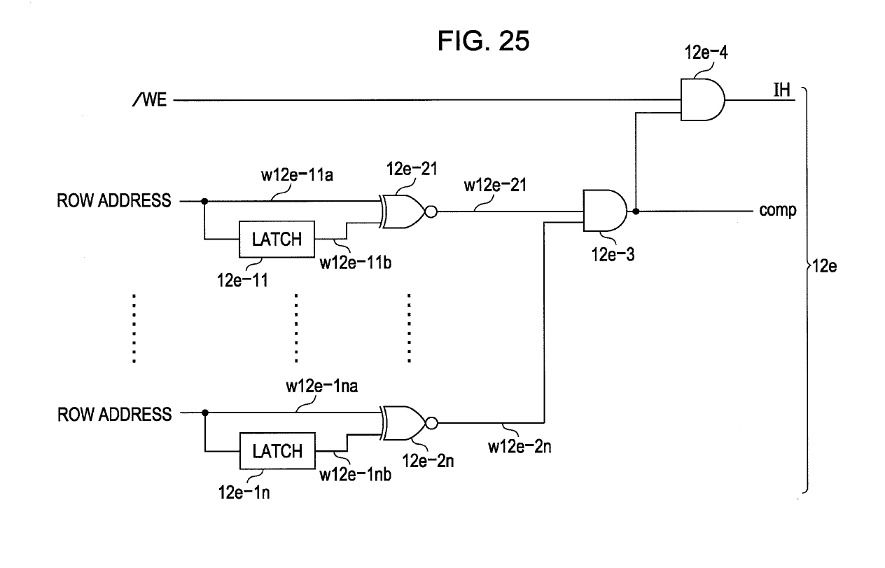

FIG. 25 illustrates a specific example of the comparator 12e. The comparator 12e illustrated in FIG. 25 has latch circuits 12e-11 to 12e-1n, ENOR circuits 12e-21 to 12e-2n, and AND circuits 12e-3 and 12e-4. The latch circuits 12e-11 to 12e-1n are provided for the corresponding row addresses. The ENOR circuits 12e-21 to 12e-2n are also prepared for the corresponding row addresses. When the value of a signal w12e-11b output from the latch 12e-11 that holds a row address in the previous cycle and the value of an input signal w12e-11a of the row address in the current cycle match each other, the ENOR circuit 12e-21 outputs a signal w12e-21 indicating “1”. Similarly, when the value of a signal w12e-1nb output from the latch 12e-1n that holds a row address in the previous cycle and the value of an input signal w12e-1na of the row address in the current cycle match each other, the ENOR circuit 12e-2n outputs a signal w12e-2n indicating “1”.

The signal w12e-21 output from the ENOR circuit 12e-21 and the signal w12e-2n output from the ENOR circuit 12e-2n are input to the AND circuit 12e-3. The AND circuit 12e-3 outputs the signal (comp), when the logic holds true. The /WE signal and the output signal of the AND circuit 12e-3 are input to the AND circuit 12e-4. The AND circuit 12e-4 activates the control signal IH when the logic of the /WE signal and the signal (comp) output from the AND circuit 12e-3 holds true.

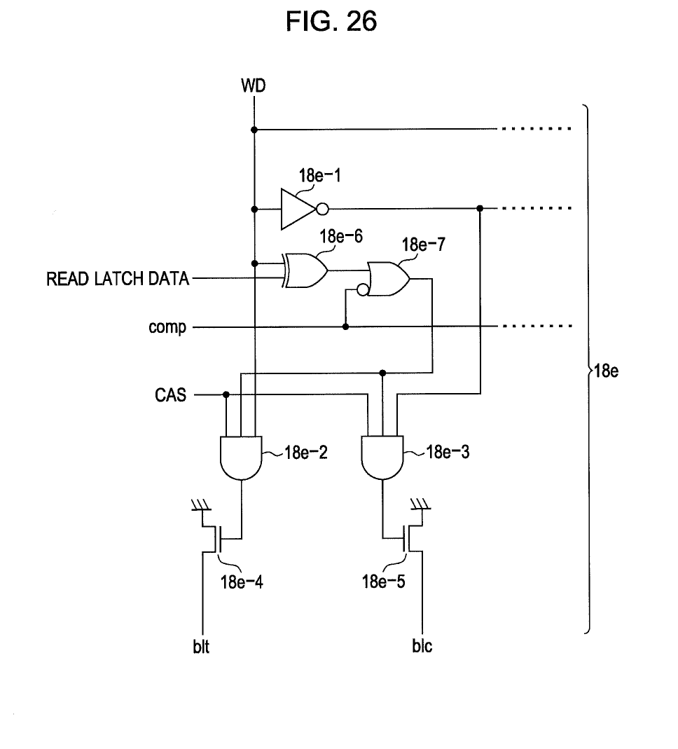

FIG. 26 illustrates a specific example of the write amplifier 18e. The write amplifier 18e has an inverter circuit 18e-1, AND circuits 18e-2 and 18e-3, transistors 18e-4 and 18e-5, an EOR circuit 18e-6, and an OR circuit 18e-7. The write amplifier 18e receives the CAS signal, the output signal (comp) of the comparator 12e, and the WD signal, and drives the potential of the bit line blt or blc to “0” in accordance with the logic of the signals.

The inverter circuit 18e-1 inverts the externally supplied WD signal and outputs the inverted WD signal to the AND circuit 18e-3. The EOR circuit 18e-6 receives the write data and the read latch data read from the read latch 24 and outputs an exclusive OR of the input signals. An inverted signal of the signal (comp) and the output signal of the EOR circuit 18e-6 are input to the OR circuit 18e-7. When the operation in the previous cycle and the operation in the current cycle are operations for writing data to the same column address and the data written matches the read latch data, the OR circuit 18e-7 operates so as not to activate the output signal. The AND circuit 18e-2 receives the CAS signal, the signal (comp), and the WD signal, and outputs a logical AND of all of the signals. The AND circuit 18e-3 receives the CAS signal, the signal (comp), and the WD signal inverted by the inverter 18e-1 and outputs a logical AND of all of the signals. The outputs of the AND circuits 18e-2 and 18e-3 are supplied to the gate terminals of the transistors 18e-4 and 18e-5, respectively. Since the input and the output of the inverter 18e-1 are connected to inputs of the AND circuits 18e-2 and 18e-3, respectively, one of the bit lines blt and blc is discharged to “0” in accordance with the signal level of the write data.

The sense amplifier 22 has the same configuration as the sense amplifier 22a illustrated in FIG. 7. Thus, regardless of the /WE signal, the sense amplifier 22 amplifies the signal level of the bit lines in accordance with the sense-amplifier enable clock. Thus, even when the /WE signal indicates the write mode, the sense amplifier 22 reads data of the memory cell to the read latch 24.

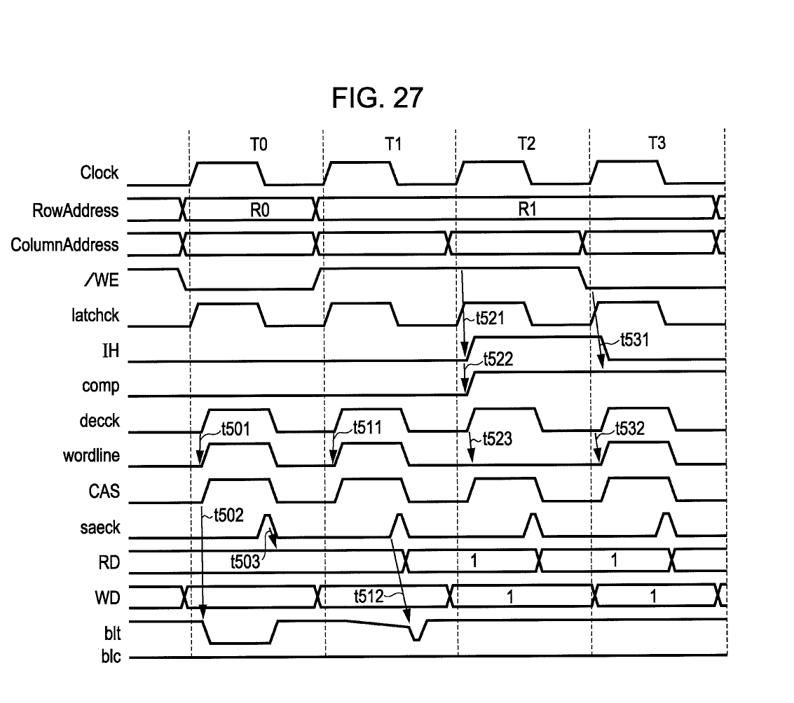

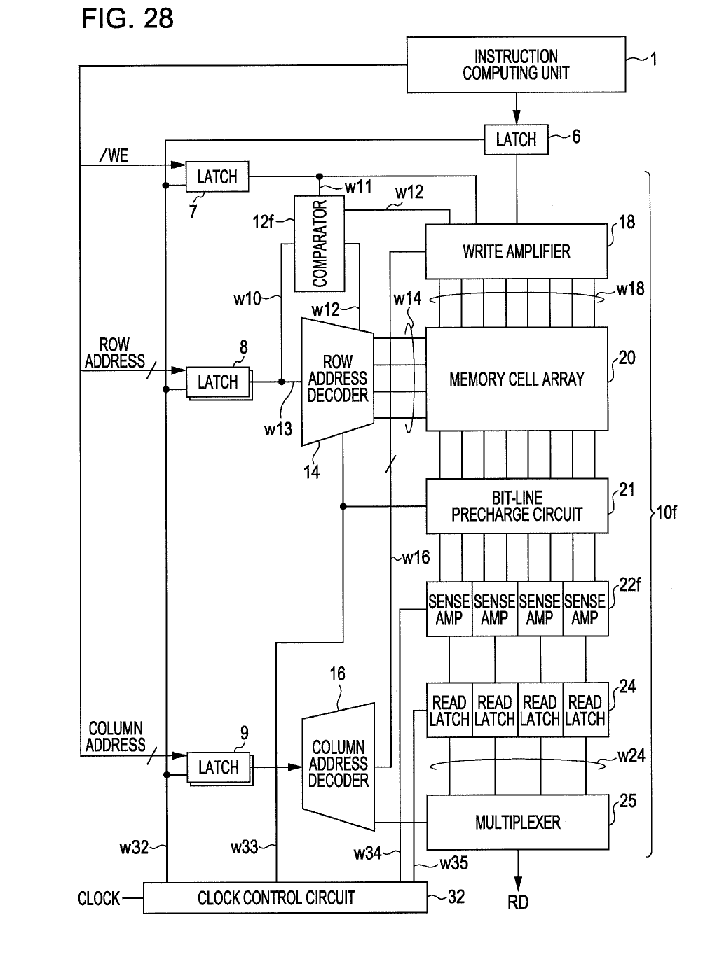

FIG. 27 illustrates one example of a timing chart of signals received by or supplied to the semiconductor memory device 10e. The semiconductor memory device 10e receives or supplies an externally supplied clock signal (Clock), a row address signal (RowAddress), a column address signal (ColumnAddress), a /WE signal, a latch clock (latchck), a control signal (IH), a signal (comp), and a decoder clock (decck). The semiconductor memory device 10e further receives or supplies a word line (wordline) signal, a CAS signal, a sense amplifier enable signal (saeck), an RD signal, a WD signal, and bit line (bit and blc) signals. The row address signal (RowAddress), the column address signal (ColumnAddress), and the RD signal are multi-bit-width signals.

In the period of time T0, since the /WE signal in the cycle T0 indicates the write mode, the comparator 12e does not activate the control signal IH. The row address decoder 14 decodes the row addresses and activates the word line (wordline), as indicated by t501. The column address decoder 16 decodes the column addresses and activates the CAS signal. Since the /WE signal indicates the write mode, the logical AND of the CAS signal and the /WE signal holds true. Thus, the write amplifier 18 drives the bit line bit to “0”, as indicated by t502, to write a bit to the memory cell specified by the word line and the bit line blt. The sense amplifier 22 is driven in accordance with the sense amplifier enable clock signal to read data from the memory cell specified by the word line and the bit line, as indicated by t503, simultaneously with the bit write operation. The sense amplifier 22 then stores the read data RD in the read latch 24.

In the period of time T1, the /WE signal is “1” indicating the read mode. However, since the row address in the cycle T0 and the row address in the cycle T1 are different from each other, the comparator 12e does not activate the control signal IH. Thus, the row address decoder 14 decodes the row addresses and activates the word line (wordline) in synchronization with the decoder clock (decck), as indicated by t511. The sense amplifier 22 is driven in accordance with the sense amplifier enable clock signal to read data from the memory cell specified by the word line and the bit line, as indicated by t512. The sense amplifier 22 then stores the read data RD in the read latch 24.

In the period of time T2, the row address “R1” in the previous cycle T1 is the same as the row address “R1” in the current cycle T2. Thus, the comparator 12e activates the control signal IH and the signal (comp), as indicated by t521 and t522. Thus, the row address decoder 14 does not activate the word line, as indicated by t523. Accordingly, the read data RD is read from the read latch 24 without reading of data from the memory cells.

In the period of time T3, the row address “R1” in the previous cycle T2 is the same as the row address “R1” in the current cycle T3. The /WE signal is “0” indicating the write mode. Thus, the comparator 12e activates the signal (comp) without activating the control signal IH, as indicated by t531. Data “1” read in the previous cycle T2 is the same as data “1” written in the current cycle T3. Thus, the write amplifier 18e does not discharge the bit lines blt and blc to “0”.

As described above, in the semiconductor memory device 10e, when the write data (WD) in the previous cycle and the write data in the current cycle are written to the same row address, the write amplifier 18e does not discharge the bit line. Accordingly, in the write mode, the circuit operation for writing data to the memory cells is eliminated, so that the power consumed is reduced.

Compared to the semiconductor memory device 10e, a semiconductor memory device 10f illustrated in FIG. 28 is different in a comparator 12f and a sense amplifier 22f. Since other configurations of the semiconductor memory device 10f are the same as those of the semiconductor memory device 10e, descriptions thereof are not given hereinafter. The modes of the comparator 12f and the sense amplifier 22f may be switched to those in the first, third, and sixth embodiments described above.

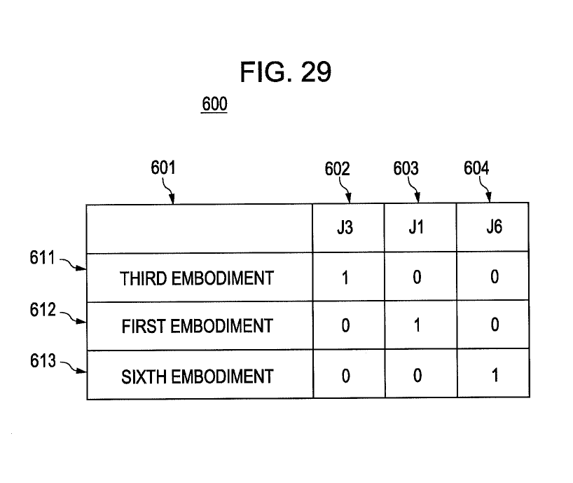

FIG. 29 is a table illustrating a logic table of mode switching signals. A logic table 600 includes a name column 601 indicating the embodiment, a column 602 indicating a signal J3 representing the third embodiment, a column 603 indicating a signal J1 representing the first embodiment, and a column 604 indicating a signal J6 representing the sixth embodiment. The semiconductor memory device 10f is connected to signal lines for receiving the signal J3, the signal J1, and the signal J6, which are externally transmitted. The semiconductor memory device 10f changes the embodiment in accordance with the signal levels of the signals J3, J1, and J6. For example, as illustrated by a first row 611, when the semiconductor memory device 10f operates in the mode of the third embodiment, the signal level of the signal J3 becomes “1” and the other signals J1 and J6 become “0”. As illustrated by a second row 612, when the semiconductor memory device 10f operates in the mode of the first embodiment, the signal level of the signal J1 becomes “1” and the other signals J3 and J6 become “0”. As illustrated by a third row 613, when the semiconductor memory device 10f operates in the mode of the sixth embodiment, the signal level of the signal J6 becomes “1” and the other signals J1 and J3 become “0”.

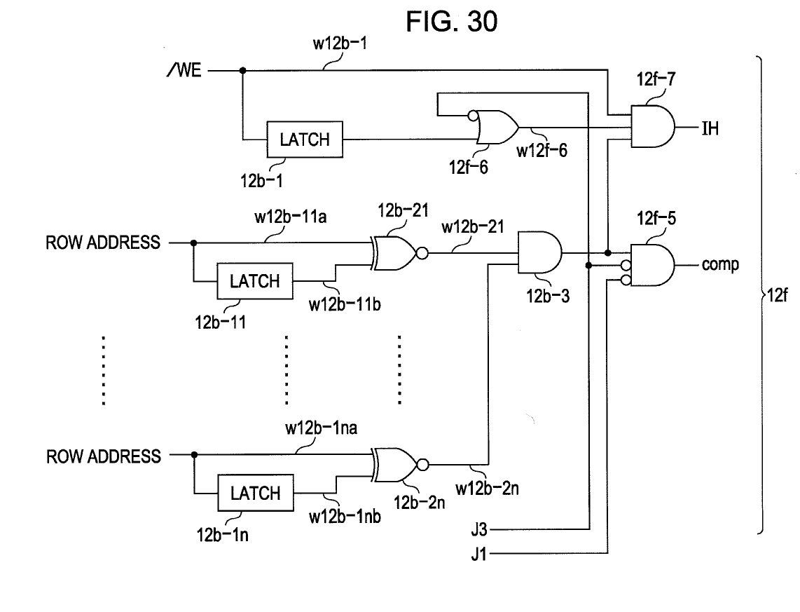

FIG. 30 illustrates a specific example of the comparator 12f. The comparator 12f has latch circuits 12b-1, 12b-11 to 12b-1n, ENOR circuits 12b-21 to 12b-2n, OR circuit 12f-6, and AND circuits 12b-3, 12f-5, and 12f-7. Since the latch circuits 12b-11 to 12b-1n, the ENOR circuits 12b-21 to 12b-2n, and the AND circuit 12b-3 have been described above in conjunction with the comparator 12b illustrated in FIG. 14, descriptions thereof are not given hereinafter.

The AND circuit 12f-5 receives a signal output from the AND circuit 12b-3, receives signals having inverted logics of the signals J3 and J1, and outputs a signal (comp). In the case of the first embodiment, the comparator 12a does not supply the signal (comp), as illustrated in FIG. 2. Thus, when the signal J1 is activated, the logic of the AND circuit 12f-5 does not hold true and the output of the AND circuit 12f-5 is not activated. In the third embodiment, the comparator 12b also does not supply the signal (comp), as illustrated in FIG. 14. Thus, when the signal J3 is activated, the logic of the AND circuit 12f-5 does not hold true and the output of the AND circuit 12f-5 is not activated. In the case of the sixth embodiment, the comparator 12e illustrated in FIG. 25 activates the signal (comp). Thus, when the signal J6 is activated, the signals J1 and J3 are deactivated as illustrated in the logic table in FIG. 29, and when the row addresses in the previous cycle and the current cycle match each other, the logic of the AND circuit 12f-5 holds true and the signal (comp) is activated.

Upon reception of the output signal of the latch circuit 12b-1 and upon input of an inverted signal of the signal J3, the AND circuit 12f-6 supplies a signal w12f-6. In the cases of the first and sixth embodiments, the /WE signal is not compared with the /WE signal in the previous cycle, as illustrated in FIG. 2, whereas in the case of the third embodiment, the /WE signal is compared with the /WE signal in the previous cycle. Thus, upon input of the inverted signal of the activated signal J3 and upon reception of the previous-cycle /WE signal that is held in the latch circuit 12b-1 and that is indicative of the read mode “1”, the AND circuit 12f-6 activates the signal w12f-6. When the received signal J3 is inactive, the AND circuit 12f-6 activates the signal w12f-6 regardless of the value of the output of the latch circuit 12b-1. With this arrangement, in the cases of the first and sixth embodiments in which the signal J3 is inactive, the signal w12f-6 is always active. In the case of the third embodiment, the activated signal J3 is inverted and is input to the AND circuit 12f-6. Thus, when the previous-cycle /WE signal data stored in the latch circuit 12b-1 indicates the read mode “1”, the signal w12f-6 is activated. The AND circuit 12f-6 operates as described above, so that, only in the third embodiment, the AND circuit 12f-6 takes a logic as to whether or not the /WE signals in the previous cycle and the current cycle indicate the read mode.

The /WE signal, the signal w12f-6, and the output of the AND circuit 12b-3 are input to the AND circuit 12f-7. When all of the input signals indicate “1”, the AND circuit 12f-7 outputs a control signal IH. As described above, in the first and sixth embodiments, the signal w12f-6 is activated. Thus, in the first and sixth embodiments, when the /WE signal indicates the read mode “1” and the row addresses in the previous cycle and the current cycle match each other, the logic of the AND circuit 12f-7 holds true. In the case of the third embodiment, when the row addresses in the previous cycle and the current cycle match each other and the /WE signals in the previous cycle and the current cycle indicate the read mode “1”, the logic holds true.

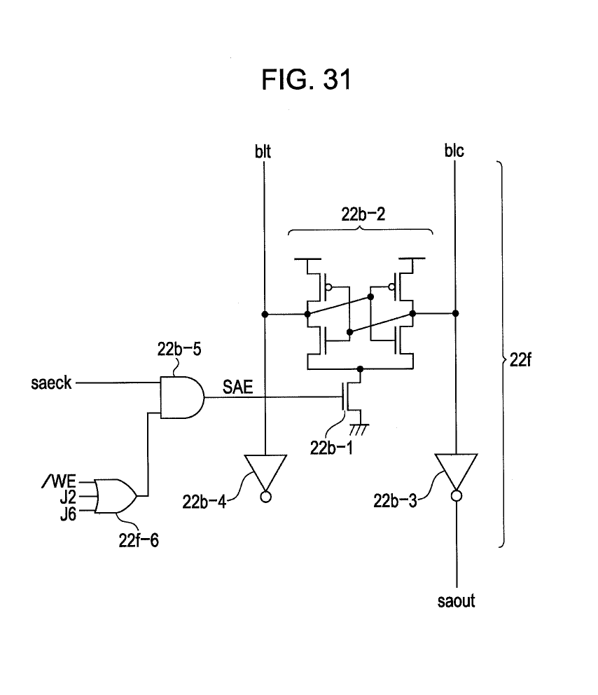

FIG. 31 illustrates a specific example of the sense amplifier 22f. The sense amplifier 22f has a transistor 22b-1, a latch circuit 22b-2, inverters 22b-3 and 22b-4, an AND circuit 22b-5, and an OR circuit 22f-6. Since the transistor 22b-1, the latch circuit 22b-2, the inverters 22b-3, and the AND circuit 22b-5 have been described above with reference to FIG. 15, descriptions thereof are not given hereinafter. The /WE signal and the signals J2 and J6 are input to the OR circuit 22f-6. Each of the sense amplifiers in the second and fifth embodiments operates in accordance with the sense amplifier enable signal clock. On the other hand, the sense amplifier 22b in the first embodiment activates the SAE signal when the /WE signal indicates the read mode and the sense amplifier enable signal clock is active. Thus, in the second and sixth embodiments, the output signal of the OR circuit 22f-6 is always activated, and in the third embodiment, the input value of the /WE signal is directly supplied as the output signal of the OR circuit 22f-6.

As described above, the semiconductor memory device 10f may change the operation mode in accordance with the externally supplied signals. Accordingly, the semiconductor memory device 10f may selectively provide the advantage of reducing word-line activation in the read mode in the first embodiment, the advantage of reducing the operation of the sense amplifier in the read mode in the third embodiment, and the advantage of reducing the operation of the write amplifier in the write mode in the sixth embodiment.

All examples and conditional language recited herein are intended for pedagogical purposes to aid the reader in understanding the embodiment and the concepts contributed by the inventor to furthering the art, and are to be construed as being without limitation to such specifically recited examples and conditions, nor does the organization of such examples in the specification relate to a illustrating of the superiority and inferiority of the embodiment. Although the embodiments of the present invention have been described in detail, it should be understood that the various changes, substitutions, and alterations could be made hereto without departing from the spirit and scope of the invention.

What is claimed is:

1. A semiconductor memory device comprising:
a plurality of memory cells that respectively stores data;
a comparator that compares a row address in a previous cycle with a row address in a current cycle, and outputs a control signal to the row address decoder when the comparator detects a matching of a row address in a previous cycle and a row address in a current cycle;
a row address decoder that decodes the row address, and outputs a word line select signal to select one of word lines connected to a part of the plurality of memory cells based on the decoded row address, and prevents the output of the word line select signal when the control signal outputted from the comparator is inputted to the row address decoder; and
a read latch that stores data read out from the part of the plurality of the memory cells selected based on the word line select signal.

2. The semiconductor memory device according to claim 1, further comprising:
a column address latch that inputs and holds column address;
a column address decoder that decodes a column address outputted from the column address latch, and outputs a column select signal to select one of column lines connected to a part of the plurality of memory cells based on the decoded column address; and
a selector that selects data outputted from the read latch based on the column select signal.

3. The semiconductor memory device according to claim 1, further comprising a write amplifier that drives one of a plurality of bit lines connected to a part of plurality of memory cells putting data in and out via the bit lines based on the column select signal, and prevents the output of the column select signal from the column address decoder when the control signal outputted from the comparator is inputted to the write amplifier.

4. The semiconductor memory device according to claim 1, further comprising a sense amplifier that receives a memory operation signal indicating either a writing operation writing data to a part of a plurality of memory cells or a reading operation reading data from a part of a plurality of memory cells, and supplies data stored in the selected a part of the plurality of memory cells to the read latch based on the word line select signal when the memory operation signal indicates the reading operation;
wherein the comparator further includes a memory operation signal latch that inputs and holds the memory operation signal, and
the comparator compares a memory operation signal inputted into the memory operation signal latch with a memory operation signal outputted from the memory operation signal latch, and outputs the control signal to the row address decoder when the comparator detects a matching of the memory operation signals and the outputted memory operation signal.

5. The semiconductor memory device according to claim 1, further comprising:
a second read latch that stores data outputted from the read latch;
wherein the comparator further includes a row address latch that inputs and holds a row address outputted from the row address latch, and
the comparator compares a row address inputted into the row address latch with a row address outputted from the row address latch, and outputs the control signal to the row address decoder, when the comparator detects a matching of the inputted row address and the outputted row address.

6. The semiconductor memory device according to claim 1, further comprising an address incrementer that generates a plurality of sequential row addresses by incrementing row address, and outputs the generated plurality of sequential row addresses to the row address decoder.

7. The semiconductor memory device according to claim 3, wherein
the comparator is disabled to compare the row address in a previous cycle with the row address in a current cycle by an inhibit signal inputted from external of the comparator, and then outputs the control signal to the write amplifier to prevent the output of the column select signal from the column address decoder.

8. A method of controlling a semiconductor memory device including a plurality of memory cells that respectively stores data, the method comprising:
comparing a row address and a delayed row address that is the row address of one cycle delayed;
outputting a control signal to a row address decoder when a matching of a row address in a previous cycle and a row address in a current cycle is detected at the comparing;
decoding a row address outputted from the row address latch by the row address decoder;
outputting a word line select signal to select one of word lines connected to a part of the plurality of cells based on the decoded row address, while preventing the output of the word line select signal when the control signal is inputted to the row address decoder; and
storing data to a read latch read out from the part of the plurality of the memory cells selected based on the word line select signal.

9. The method according to claim 8, wherein the semiconductor memory device further includes a plurality of column address latches that inputs and holds column address, the method further comprising:
decoding a column address outputted from a column address latch;
outputting a column select signal to select one of column lines connected to a part of the plurality of memory cells based on the decoded column address; and
selecting data outputted from the read latch based on the column select signal.

10. The method according to claim 8, further comprising:
driving one of a plurality of bit lines connected to a part of plurality of memory cells putting data in and out via the bit lines based on the column select signal by a write amplifier; and
preventing the output of the column select signal, when the control signal is inputted to the write amplifier.

11. The method according to claim 8, wherein the semiconductor memory device further includes a memory operation signal latch that inputs and holds a memory operation signal indicating either a writing operation writing data to a part of a plurality of memory cells or a reading operation reading data from a part of a plurality of memory cells, the method further comprises
comparing a memory operation signal inputted into the memory operation signal latch with a memory operation signal outputted from the memory operation signal latch, and
outputting the control signal to the row address decoder, when the inputted memory operation signal and the outputted memory operation signal are matched from each other.

12. The method according to claim 8, wherein the semiconductor memory device further comprises a second read latch that stores data outputted from the read latch and a row address latch that inputs and holds a row address outputted from the row address latch, the method further comprising:
comparing a row address inputted into the row address latch with a row address outputted from the row address latch; and
outputting the control signal to the row address decoder, when the comparator detects a matching of the inputted row address and the outputted row address.

13. The method according to claim 8, further comprising:
generating a plurality of sequential row addresses by incrementing row address; and
outputting the generated plurality of sequential row addresses to the row address decoder

14. The method according to claim 8, the method further comprises disabling a comparison of an inhibit signal inputted from external of the comparator, and then outputs the control signal to the write amplifier to prevent the output of the column select signal from the column address decoder.
